(19) United States
(12) Patent Application Publication
(10) Pub. No.: US 2025/0221063 A1
(43) Pub. Date: Jul. 3, 2025

(54) IMAGE SENSOR

(71) Applicant: Samsung Electronics Co., Ltd., Suwon-si (KR)

(72) Inventor: Changyong UM, Suwon-si (KR)

(73) Assignee: Samsung Electronics Co., Ltd., Suwon-si (KR)

(21) Appl. No.: 18/897,515

(22) Filed: Sep. 26, 2024

(30) Foreign Application Priority Data
Jan. 3, 2024 (KR) 10-2024-0001194

(51) Int. Cl. H01L 27/146

(52) U.S. Cl. CPC H10F 39/18; H10F 39/8037; H10F 39/807; H10F 39/809; H10F 39/811

(57) ABSTRACT

An image sensor includes a semiconductor substrate including opposite first and second surfaces, photodiodes within the semiconductor substrate, and driving transistors to generate electrical signals based on outputs from the photodiodes. The driving transistors include a fin-type active region including channel regions corresponding to separate, respective driving transistors, and source-drain regions protruding perpendicularly to the first surface, adjacent source-drain regions at opposite sides of each channel region, and a driving gate electrode to cover a top surface and opposite sidewalls of the fin-type active region. Adjacent driving transistors physically share a source-drain region that is between the adjacent driving transistors such that the source-drain region is a source region or a drain region of each of the adjacent driving transistors.

### CROSS-REFERENCE TO RELATED APPLICATION

This application claims priority under 35 U.S.C. § 119 to Korean Patent Application No. 10-2024-0001194 filed on Jan. 3, 2024, in the Korean Intellectual Property Office, the disclosures of which are incorporated by reference herein in their entireties.

### BACKGROUND

Example embodiments of the present inventive concepts described herein relate to image sensors and more particularly, relate to image sensors having a transistor having a finFET structure.

An image sensor is a device to convert an optical image signal into an electrical signal. The image sensor includes a plurality of pixels. Each pixel includes a photodiode region to receive incident light incident and to convert the incident light into an electrical signal, and a pixel circuit to output a pixel signal using charges generated from the photodiode region. As the integration degree of the image sensor is increased, the size of each pixel is decreased, and the size of a component of each pixel circuit is decreased. Accordingly, as the area of a channel of a driving transistor included in the image sensor is decreased, noise is increased.

### SUMMARY

some example embodiments of the present inventive concepts provide an image sensor capable of reducing or minimizing noise resulting from the decrease in an area of a channel of a transistor.

According to some example embodiments of the present inventive concepts, an image sensor may include a semiconductor substrate, the semiconductor substrate including a first surface and a second surface opposite to each other. The image sensor may include photodiodes within the semiconductor substrate. The image sensor may include a plurality of driving transistors configured to generate electrical signals based on outputs from the photodiodes. The plurality of driving transistors may include a fin-type active region. The fin-type active region may include channel regions and source-drain regions. The channel regions may correspond to separate, respective driving transistors of the plurality of driving transistors. Adjacent source-drain regions among the source-drain regions may be at opposite sides of each channel region among the channel regions. The source-drain regions may protrude perpendicularly to the first surface. The plurality of driving transistors may include a driving gate electrode configured to cover a top surface and opposite sidewalls of the fin-type active region. Adjacent driving transistors among the plurality of driving transistors may physically share a particular source-drain region among the source-drain regions that is between the two adjacent driving transistors such that the particular source-drain region is a source region or a drain region of each of the two adjacent driving transistors.

According to some example embodiments of the present inventive concepts, an image sensor may include a pixel array including a plurality of pixels including photodiodes and arranged in a matrix form in a first direction and a second direction crossing the first direction, and a micro-lens on the pixel array and configured to condense light incident onto the plurality of pixels. The pixel array may include a semiconductor substrate including a first surface and a second surface opposite to each other, the photodiodes may be within the semiconductor substrate, and the pixel array may include a plurality of driving transistors configured to generate electrical signals based on outputs of the photodiodes. The plurality of driving transistors may include a fin-type active region. The fin-type active region may include channel regions corresponding to separate, respective driving transistors of the plurality of driving transistors. The fin-type active region may include source-drain regions. Adjacent source-drain regions among the source-drain regions may be at opposite sides of each channel region among the channel regions. The source-drain regions may protrude perpendicularly to the first surface. The plurality of driving transistors may include a driving gate electrode configured to cover a top surface and opposite sidewalls of the fin-type active region. Two adjacent driving transistors among the plurality of driving transistors may physically share a particular source-drain region among the source-drain regions that is between the two adjacent driving transistors such that the particular source-drain region is a source region or a drain region of each of the two adjacent driving transistors.

According to some example embodiments of the present inventive concepts, an image sensor may include a first structure including a plurality of pixels; and a second structure stacked together with the first structure, the second structure including a logic circuit configured to control the plurality of pixels. Each pixel of the plurality of pixels may include a semiconductor substrate, the semiconductor substrate including a first surface and a second surface opposite to each other. Each pixel of the plurality of pixels may include photodiodes within the semiconductor substrate. Each pixel of the plurality of pixels may include a plurality of driving transistors configured to generate electrical signals based on outputs of the photodiodes. The plurality of driving transistors may include a fin-type active region. The fin-type active region may include channel regions corresponding to separate, respective driving transistors of the plurality of driving transistors. The fin-type active region may include source-drain regions. Adjacent source-drain regions among the source-drain regions may be at opposite sides of each channel region among the channel regions. The source-drain regions may protrude perpendicularly to the first surface. The plurality of driving transistors may include a driving gate electrode configured to cover a top surface and opposite sidewalls of the fin-type active region. Two adjacent driving transistors among the plurality of driving transistors may physically share a particular source-drain region among the source-drain regions that is between the two adjacent driving transistors such that the particular source-drain region is a source region or a drain region of each of the two adjacent driving transistors.

### BRIEF DESCRIPTION OF THE DRAWINGS

The above and other objects and features of the present inventive concepts will become apparent by describing in detail example embodiments thereof with reference to the accompanying drawings.

FIG. 1 is a block diagram of an image sensor according to some example embodiments of the present inventive concepts.

FIG. 2A is a view conceptually illustrating the layout of an image sensor according to some example embodiments of the present inventive concepts, and FIG. 2B is a plan view conceptually illustrating a first structure in FIG. 2A according to some example embodiments of the present inventive concepts.

FIG. 3 is an equivalent circuit diagram of a pixel of an image sensor according to some example embodiments of the present inventive concepts, and is a circuit diagram corresponding to one pixel in FIGS. 2A and 2B.

FIG. 4 is an enlarged plan view of a part P1 of FIG. 2B according to some example embodiments of the present inventive concepts.

FIG. 5A is a cross-sectional view taken along line A-A′ of FIG. 4 according to some example embodiments of the present inventive concepts, FIG. 5B is a cross-sectional view taken along line B-B′ of FIG. 4 according to some example embodiments of the present inventive concepts, and FIG. 5C is an enlarged view of a part P3 of FIG. 5A according to some example embodiments of the present inventive concepts.

FIGS. 6A and 6B illustrate an electrical connection relationship of driving transistors according to some example embodiments of the present inventive concepts.

FIG. 7A is an equivalent circuit diagram of one pixel in an image device according to some example embodiments of the present inventive concepts, FIG. 7B is a plan view illustrating a part of the pixel according to some example embodiments and a part corresponding to a part P2 of FIG. 4 according to some example embodiments of the present inventive concepts, and FIG. 7C illustrates an electrical connection relationship of the driving transistor illustrated in FIG. 7B according to some example embodiments of the present inventive concepts.

FIG. 8A is an equivalent circuit diagram of one pixel in an image device according to some example embodiments of the present inventive concepts, FIG. 8B is a plan view illustrating a part of the pixel according to some example embodiments and a part corresponding to a part P2 of FIG. 4 according to some example embodiments of the present inventive concepts, and FIG. 8C illustrates an electrical connection relationship of the driving transistor illustrated in FIG. 8B according to some example embodiments of the present inventive concepts.

FIG. 9A is a plan view illustrating a part of the pixel according to some example embodiments, and a part corresponding to P2 of FIG. 4 according to some example embodiments of the present inventive concepts, and FIG. 9B illustrates an electrical connection relationship of the driving transistor illustrated in FIG. 9A according to some example embodiments of the present inventive concepts.

FIG. 10A is a plan view illustrating a part of the pixel corresponding to part P2 of FIG. 4 according to some example embodiments of the present inventive concepts, and FIG. 10B is a view illustrating an electrical connection relationship between driving transistors and the selection transistor illustrated in FIG. 10A according to some example embodiments of the present inventive concepts.

FIG. 11A is a plan view illustrating a part of the pixel corresponding to part P2 of FIG. 4 according to some example embodiments of the present inventive concepts, and FIG. 11B is a view illustrating an electrical connection relationship of the driving transistor illustrated in FIG. 11A according to some example embodiments of the present inventive concepts.

FIG. 12 is a cross-sectional view illustrating a two-stack structure in which a first structure and a second structure are stacked in an image sensor according to some example embodiments of the present inventive concepts.

### DETAILED DESCRIPTION

While the present inventive concepts are susceptible to various modifications and alternative forms, specific embodiments thereof are shown by way of example in the drawings and will be described herein in detail. It should be understood, however, that there is no intent to limit the present inventive concepts to the particular forms disclosed, but on the contrary, the present inventive concepts are to cover all modifications, equivalents, and alternatives falling within the spirit and scope of the inventive concepts.

Hereinafter, some example embodiments of the present inventive concepts will be described in more detail with reference to accompanying drawings.

Hereinafter, the technical spirit of embodiments of the present inventive concepts will be described in detail with reference to accompanying drawings. The same components in the drawings will be assigned with the same reference numerals, and the detail thereof will be omitted to avoid redundancy.

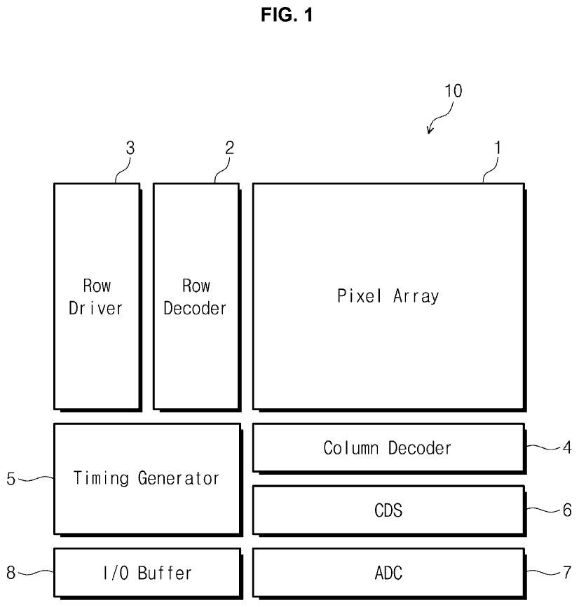

FIG. 1 is a block diagram of an image sensor according to some example embodiments of the present inventive concepts.

Referring to FIG. 1, an image sensor 10 according to some example embodiments of the present inventive concepts includes a pixel array 1, a row decoder 2, a row driver 3, a column decoder 4, a timing generator 5, a correlated double sampler (CDS) 6, an analog to digital converter (ADC) 7, and an input/output (I/O) buffer 8.

The pixel array 1 includes a plurality of unit pixels arranged in two dimensions and converts an optical signal into an electrical signal. The pixel array 1 may be driven in response to a plurality of driving signals, such as a pixel selecting signal, a reset signal, and a charge transferring signal which are received from the row driver 3. In addition, the converted electrical signal is applied to the correlated double sampler 6.

The row driver 3 provides the plurality of driving signals, which are for driving a plurality of unit pixels, to the pixel array 1, depending on a decoding result of the row decoder 2. When the unit pixels are arranged in a matrix form, the driving signals may be provided each row.

The timing generator 5 provides a timing signal and a control signal to the row decoder 2 and the column decoder 4.

The correlated double sampler 6 receives holds, and samples the electrical signal generated from the pixel array 1. The correlated double sampler performs a sampling operation for a specific noise level and a signal level of the electrical signal dually, and outputs a difference level corresponding to a difference between the specific noise level and the signal level.

The ADC 7 converts an analog signal corresponding to the difference level output from the CDS 6 into a digital signal and outputs the digital signal.

The I/O buffer 8 latches the digital signal, and sequentially outputs the latched digital signal to an image signal processing unit (not illustrated) depending on the decoding result of the column decoder 4.

As described herein, any devices, systems, modules, portions, units, controllers, circuits, and/or portions thereof according to any of the example embodiments, and/or any portions thereof (including, without limitation, the image sensor 10, the pixel array 1, the row decoder 2, the row driver 3, the column decoder 4, the timing generator 5, the correlated double sampler (CDS) 6, the analog to digital converter (ADC) 7, the input/output (I/O) buffer 8, any portion thereof, or the like) may include, may be included in, and/or may be implemented by one or more instances of processing circuitry such as hardware including logic circuits; a hardware/software combination such as a processor executing software; or a combination thereof. For example, the processing circuitry more specifically may include, but is not limited to, a central processing unit (CPU), an arithmetic logic unit (ALU), a graphics processing unit (GPU), an application processor (AP), a digital signal processor (DSP), a microcomputer, a field programmable gate array (FPGA), and programmable logic unit, a microprocessor, application-specific integrated circuit (ASIC), a neural network processing unit (NPU), an Electronic Control Unit (ECU), an Image Signal Processor (ISP), and the like. In some example embodiments, the processing circuitry may include a non-transitory computer readable storage device (e.g., a memory), for example a solid state drive (SSD), storing a program of instructions, and a processor (e.g., CPU) configured to execute the program of instructions to implement the functionality and/or methods performed by some or all of any devices, systems, modules, portions, units, controllers, circuits, and/or portions thereof according to any of the example embodiments.

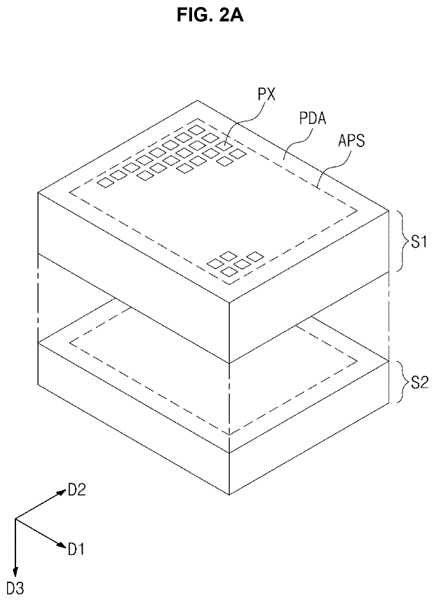

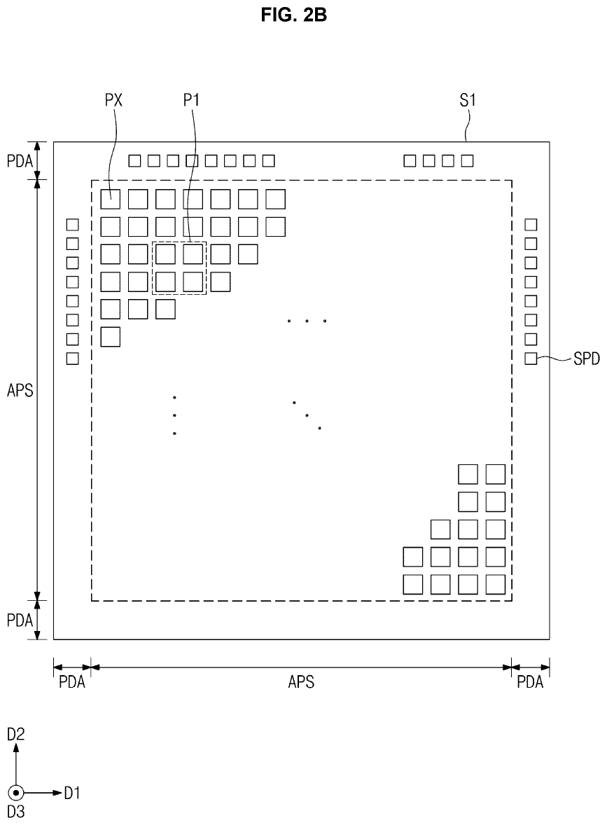

FIG. 2A is a view conceptually illustrating the layout of an image sensor according to some example embodiments of the present inventive concepts, and FIG. 2B is a plan view conceptually illustrating a first structure in FIG. 2A according to some example embodiments of the present inventive concepts.

Referring to FIGS. 2A and 2B, the image sensor may include two structures which are sequentially stacked in one direction. For example, as illustrated in FIG. 2A, the image sensor may include a first structure S1 and a second structure S2 which are stacked on one another.

The first structure S1 and the second structure S2 may be provided in the form of a chip, and may have an equal size or mutually different sizes. For example, when viewed in a plan view, the area of the first structure S1 may be smaller than the area of the second structure S2.

A bonding part (not illustrated) to bond two structures may be provided between the first structure S1 and the second structure S2 adjacent to each other. In the following description, a direction in which the first structure S1 and the second structure S2 are stacked is defined as a third direction D3, and two directions intersecting each other on a plane perpendicular to the third direction D3 are referred to as a first direction D1 and a second direction D2. However, in the present description, the first to third directions D1, D2, and D3 are relative directions set for the convenience of explanation, and may be configured in directions different from the directions in an actual object. Herein, the first and second directions D1 and D2 may each be referred to as a horizontal direction, and the third direction D3 may be referred to as a vertical direction.

The first structure S1 may be a sensor structure in which a plurality of pixels PX are formed.

The first structure S1 may include a pixel array region APS, which is a region arranged in a two-dimensional array structure of the plurality of pixels PX when viewed in a plan view, and a pad region PDA disposed on at least one side of the ALC pixel array region APS. The pixel array region APS may be disposed at the central portion of the first structure S1 when viewed in a plan view.

The pixels PX may output a photoelectric signal from incident light. The pixels PX may be two-dimensionally arranged while forming rows and columns in the first and second directions D1 and D2. The pad region PDA may be an edge region of the first structure S1. When viewed in a plan view, the pad region PDA may surround the pixel array region APS. Signal pads SPD may be provided on the pad region PDA. The signal pads SPD may output an electrical signal generated from the pixels PX to the outside. In some example embodiments, an external electrical signal or voltage may be transmitted to the pixels PX through the signal pads SPD. Since the pad region PDA is an edge region of a semiconductor substrate, the signal pads SPD may be easily connected to the outside. However, the placement of the pad region PDA is not limited thereto and may be provided, for example, to the second structure S2.

The second structure S2 may have a logic circuit to control the plurality of pixels PX mounted on the second structure S2. Logic circuits may include circuits to process pixel signals from the pixels. For example, the logic circuits may include a control register block, a timing generator, a row driver, a readout circuit, or a ramp signal generator. According to some example embodiments of the present inventive concepts, a memory device may be further disposed on the second structure S2. The memory device may be embedded therein with a dynamic random access memory (DRAM) device, a static random access memory (SRAM) device, a spin transfer torque random access memory (STT-MRAM) device, and a flash memory device. The image sensor may improve operating characteristics of the image sensor by temporarily storing a frame image and by performing signal processing using such a memory device. In addition, since the memory device of the image sensor is formed together with the logic device, in an embedded form. Accordingly, a fabricating process may be simplified and the size of a product may be reduced, thereby improving miniaturization of the product while also reducing fabrication costs and reducing the likelihood of fabrication process defects in the product due to the simplified fabricating process.

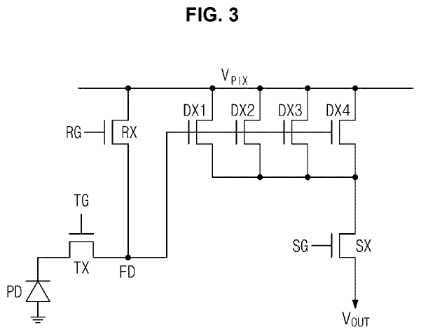

FIG. 3 is an equivalent circuit diagram of a pixel of an image sensor according to some example embodiments, and is a circuit diagram corresponding to one pixel PX of the pixels PX in FIGS. 2A and 2B.

Referring to FIG. 3, each of the pixels PX may include a photodiode PD and a pixel transistor (e.g., a transfer transistor TX, a reset transistor RX, a selection transistor SX, and a driving transistor DX; see FIG. 3).

The photodiode PD may generate and accumulate electric charges depending on an amount or intensity of incident light. The photodiode PD may be referred to as a photodetector implemented with a photo transistor, a photo gate, a pinned photo diode (PPD), an organic photo diode (OPD), a quantum dot (QD), etc.

The transfer transistor TX may be turned on or off in response to a transfer signal TG provided from the row decoder (see FIG. 1). The transfer transistor TX may transfer the charges accumulated in the photodiode PD to a floating diffusion region FD. To this end, a drain of the transfer transistor TX may be connected to the photodiode PD. In addition, a source of the transfer transistor TX may be connected to the floating diffusion region FD.

The floating diffusion region FD may be connected to a source of the transfer transistor TX, a source of the reset transistor RX, and a gate of the driving transistor DX.

The reset transistor RX may be turned on or off in response to a reset signal RG. More specifically, the reset transistor RX may be turned on in response to the reset signal RG for applying a reset voltage to the gate of the driving transistor DX.

For example, the reset transistor RX may be turned on in response to the reset signal RG activated, and a power supply voltage V_{PIX} may be transferred to the floating diffusion region FD. In some example embodiments, the voltage of the floating diffusion region FD may be reset to the level of the power supply voltage V_{PIX}. To this end, the drain of the reset transistor RX may be connected to the power supply voltage V_{PIX}. In addition, the source of the reset transistor RX may be connected to the floating diffusion region FD.

The driving transistor DX may generate a source-drain current according to the intensity of optical charges applied to the gate of the driving transistor DX. More specifically, the driving transistor DX may generate the source-drain current proportional to the intensity of the optical charge applied to the gate of the driving transistor DX from the floating diffusion region FD. To this end, the gate of the driving transistor DX may be connected to the floating diffusion region FD. In addition, the drain of the driving transistor DX may be connected to the power supply voltage V_{PIX}.

The driving transistor DX may serve as a source follower amplifier. For example, the driving transistor DX may amplify the potential change of the floating diffusion region FD. Furthermore, the driving transistor DX may output the amplified potential change via the selection transistor SX.

According to some example embodiments of the present inventive concepts, a plurality of driving transistors DX may be provided and connected in parallel to each other. According to some example embodiments of the present inventive concepts, four driving transistors DX may include a first driving transistor DX1, a second driving transistor DX2, a third driving transistor DX3, and a fourth driving transistor DX4. In some example embodiments, the first to fourth driving transistors DX1, DX2, DX3, and DX4 may have drains connected to the power supply voltage V_{PIX}, respectively and sources connected to the selection transistor SX. As shown, the first to fourth driving transistors DX1, DX2, DX3, and DX4 may be connected to each other in parallel, for example in parallel between the power supply voltage V_{PIX} and the selection transistor SX. In some example embodiments, the first to fourth driving transistors DX1, DX2, DX3, and DX4 may be interchangeably referred to as a driving transistor DX or a plurality of driving transistors.

Through the above-described configuration, each pixel may have a driving transistor implemented with an increased channel width and an increased channel length. In the following description, unless otherwise stated, the driving transistor DX refers to a structure in which the plurality of driving transistors are connected in parallel.

The selection transistor SX may be used when selecting the pixel PX to be read in unit of a row. The selection transistor SX may be driven in response to a selection signal SG provided in unit of a row. When the selection transistor SX is turned on, the potential of the floating diffusion region FD may be amplified and transmitted to the drain of the selection transistor SX through the driving transistor DX. The selection transistor SX may output (e.g., transmit) a signal received from the driving transistors DX in response to being driven by the selection signal SG.

As described above, the optical charges generated through the photodiode PD may be output as image data through the transfer transistor TX, the floating diffusion region FD, the driving transistor DX, and the selection transistor SX.

In some example embodiments, the image sensor according to some example embodiments of the present inventive concepts may reduce noise of an output signal Vout by including the driving transistor DX having an increased channel width, and thus the functionality (e.g., image generating functionality, image generating performance, etc.) of the image sensor may be improved based on including the driving transistor DX (e.g., plurality of driving transistors according to some example embodiments).

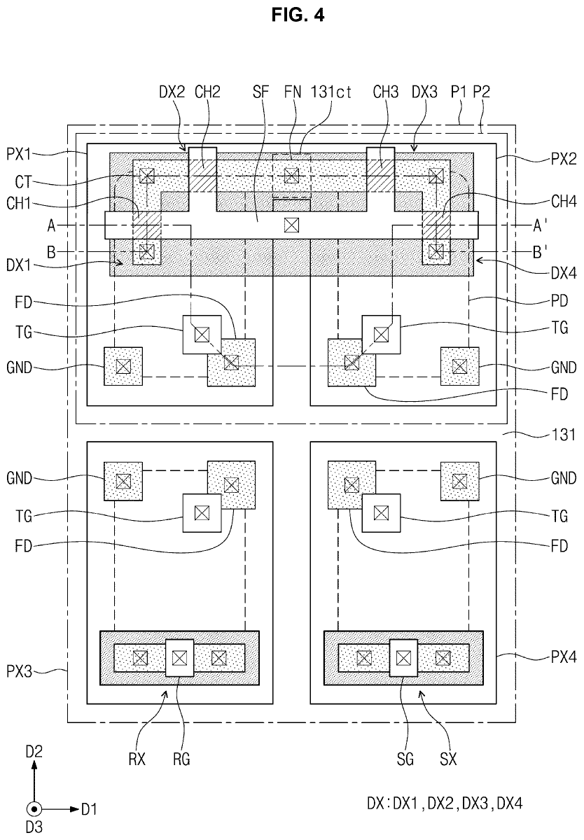

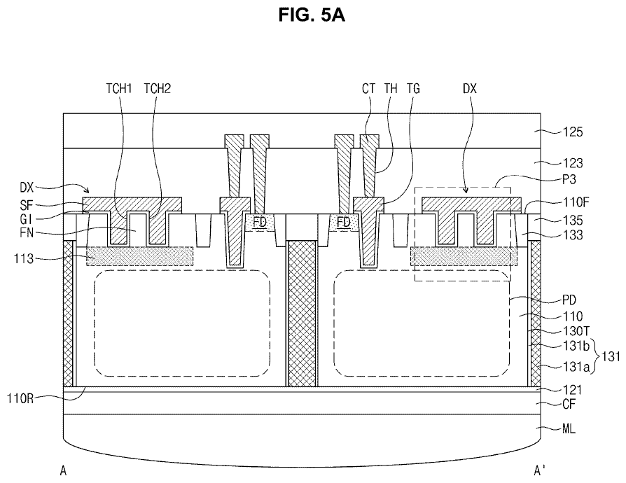

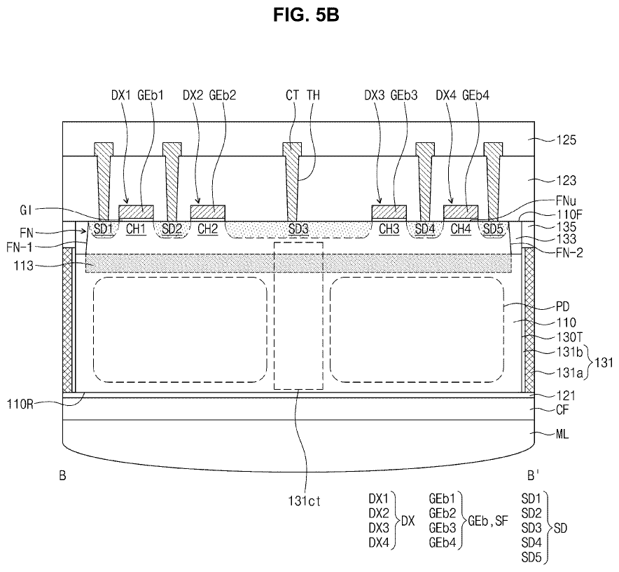

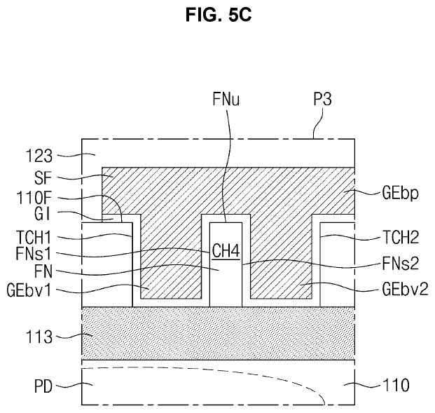

FIG. 4 is an enlarged plan view of a part P1 of FIG. 2B according to some example embodiments of the present inventive concepts. FIG. 5A is a cross-sectional view taken along line A-A′ of FIG. 4 according to some example embodiments of the present inventive concepts, FIG. 5B is a cross-sectional view taken along line B-B′ of FIG. 4 according to some example embodiments of the present inventive concepts, and FIG. 5C is an enlarged view of part P3 of FIG. 5A according to some example embodiments of the present inventive concepts.

Referring to FIGS. 3, 4, and 5A to 5C, the pixels PX are provided to the semiconductor substrate in the pixel array region APS.

A semiconductor substrate 110 may have a first surface 110F and a second surface 110R facing each other (e.g., opposite to each other). The first surface 110F of the semiconductor substrate 110 may be a front surface, and the second surface 110R may be a rear surface. Light may be incident on the second surface 110R of the semiconductor substrate 110. The semiconductor substrate 110 may be a semiconductor substrate or a silicon-on-insulator SOI substrate. The semiconductor substrate 110 may include, for example, Si, Ge, SiC, GaAs, InAs, or InP. The semiconductor substrate 110 may further include a Group III element. The Group III element may be an impurity in a first conductivity type. Accordingly, the semiconductor substrate 110 may have the first conductivity type. For example, the impurity in the first conductivity type may include p-type impurities such as aluminum (Al), boron (B), indium (In), and/or gallium (Ga). According to some example embodiments of the present inventive concepts, the semiconductor substrate 110 may include a p-type bulk substrate and a p-type or n-type epitaxial layer grown on the p-type bulk substrate. According to some example embodiments, the semiconductor substrate 110 may include an n-type bulk substrate and a p-type or n-type epitaxial layer grown thereon. In some example embodiments, the semiconductor substrate 110 may include an organic plastic substrate. Although the following description will be made regarding that the first conductivity type is a p-type, this is merely provided only for the illustrative purpose. For example, the first conductivity type may be an n-type.

The semiconductor substrate 110 includes the photodiode PD for each pixel PX. The photodiode PD may be interposed between the first surface 110F and the second surface 110R of the semiconductor substrate 110 and thus may be within the semiconductor substrate 110. The photodiode PD may be a region including the second conductivity type. For example, the photodiode PD may be defined as a region within the semiconductor substrate 110 that includes a material having the second conductivity type (e.g., second conductivity type impurity). According to some example embodiments of the present inventive concepts, the photodiode PD may include a group V element, and the group V element may be a second conductivity type impurity. The second conductivity type impurity may have a conductivity type opposite to the first conductivity type impurity. The second conductivity type impurity may include an n-type impurity such as phosphorus, arsenic, bismuth, and/or antimony. The photodiode PD may be disposed at a position spaced apart from the second surface 110R of the semiconductor substrate 110.

A device isolation layer 131 is disposed in the semiconductor substrate 110, and the plurality of pixels PX may be defined by the device isolation layer 131. The device isolation layer 131 may be interposed between a first photodiode PD from among the plurality of photodiodes PD and a second photodiode PD adjacent to the first photodiode PD. The first photodiode PD and the second photodiode PD adjacent to the first photodiode PD may be physically and electrically separated from each other by the device isolation layer 131. The device isolation layer 131 is interposed between the plurality of photodiodes PD arranged in a matrix form, and may have a grid or mesh form, when viewed in a plan view.

The device isolation layer 131 may be, for example, provided in the form in which an insulating material is filled in a deep trench formed by patterning the semiconductor substrate 110, in other words, a deep trench isolation film (DTI). The device isolation layer 131 may be formed in a pixel trench 130T formed through the semiconductor substrate 110 from the first surface 110F to the second surface 110R of the semiconductor substrate 110 (e.g., a pixel trench 130T defined by one or more inner surfaces of the semiconductor substrate 110 extending from the first surface 110F to the second surface 110R of the semiconductor substrate 110). The device isolation layer 131 may include an insulating liner 131b conformally formed on a sidewall of the pixel trench 130T, a conductive layer 131a filling the inside of the pixel trench 130T on the insulating liner 131b, and an upper insulating layer 135. The conductive layer 131a may include a metal or a crystalline semiconductor material, for example, polysilicon. According to some example embodiments of the present inventive concepts, the conductive layer 131a may further include a dopant, and the dopant may include an impurity in the first conductivity type or the second conductivity type. For example, the conductive layer 131a may include doped polysilicon. A negative voltage or a ground voltage may be applied to the conductive layer 131a, thereby improving a dark current. The upper insulating layer 135 may be disposed in a portion, which is adjacent to the first surface 110F of the semiconductor substrate 110, of the pixel trench 130T.

According to some example embodiments of the present inventive concepts, the pixel trench 130T is formed to extend from the first surface 110F of the semiconductor substrate 110 toward the second surface 110R of the semiconductor substrate 110, through an inner portion of the semiconductor substrate 110, and the insulating liner 131b and the conductive layer 131a may be sequentially formed inside the pixel trench 130T. Thereafter, the upper insulating layer 135 may be formed by filling an insulating material a remaining space after partially etching back the insulating liner 131b and the conductive layer 131a disposed at the entrance of the pixel trench 130T. According to some example embodiments, the pixel trench 130T is formed to extend from the second surface 110R of the semiconductor substrate 110 toward the first surface 110F of the semiconductor substrate 110 through the inner portion of the semiconductor substrate 110, and then the insulating liner 131b and the conductive layer 131a may be sequentially formed inside the pixel trench 130T. In the present specification, it may be recognized that the expression “the pixel trench 130T or the device isolation layer 131 extends from the first surface 110F of the semiconductor substrate 110 to the second surface 110R of the semiconductor substrate 110” includes both a case where the pixel trench 130T is formed to extend from the first surface 110F of the semiconductor substrate 110 toward the second surface 110R of the semiconductor substrate 110 and a case where the pixel trench 130T is formed to extend from the second surface 110R of the semiconductor substrate 110 to the first surface 110F of the semiconductor substrate 110.

According to some example embodiments of the present inventive concepts, the insulating liner 131b may include a metal oxide, such as hafnium oxide, aluminum oxide, tantalum oxide, etc. In some example embodiments, the insulating liner 131b may function as a negative fixed charge layer, but the technical spirit of the present inventive concepts is not limited thereto. According to some example embodiments, the insulating liner 131b may include an insulating material such as silicon oxide, silicon nitride, silicon oxynitride, etc.

Although the device isolation layer 131 extends from the first surface 110F of the semiconductor substrate 110 to the second surface 110R of the semiconductor substrate 110, through the semiconductor substrate 110 according to some example embodiments of the present inventive concepts, the device isolation layer 131 may extend from the second surface 110R of the semiconductor substrate 110 toward the inner portion of the semiconductor substrate 110 and may not be exposed to the first surface 110F of the semiconductor substrate 110 according to some example embodiments. In some example embodiments, a barrier doping region (not illustrated) may be formed between one end, which is adjacent to the first surface 110F of the semiconductor substrate 110, of the device isolation layer 131, and the first surface 110F. The barrier doping region may be a region heavily doped with p-type impurities at a high concentration.

According to some example embodiments of the present inventive concepts, a shallow device isolation layer 133 may be formed on the first surface 110F of the semiconductor substrate 110 to define an active region (not illustrated) for disposing pixel transistors constituting the pixel circuit. The shallow device isolation layer 133 may be disposed in a device isolation trench formed to a predetermined depth on the first surface 110F of the semiconductor substrate 110, and may include an insulating material. The shallow device isolation layer 133 may be disposed to surround an upper sidewall (e.g., a sidewall of the upper insulating layer 135) of the device isolation layer 131.

The active region may be a portion of the semiconductor substrate 110 for disposing the gate, the source, and the drain of each of the transfer transistor TX, the driving transistor DX, the selection transistor SX, and the reset transistor RX. A region for disposing the gate, the source, and the drain of the pixel transistors may be a fin-type active region FN. The active region may also include a ground region GND and the floating diffusion region FD. The ground region GND, the floating diffusion region FD, and the fin-type active region FN may be disposed to be spaced apart from each other by the shallow device isolation layer 133.

In some example embodiments, the gate, the source, and the drain of each pixel transistor correspond to a gate electrode, a source region, and a drain region on the active region of the semiconductor substrate 110. Hereinafter, when viewed in a plan view, the gates of the transfer transistor TX, the selection transistor SX, and the reset transistor RX, which receive the transfer signal TG, the selection signal SG, and the reset signal RG of FIG. 3 are assigned with reference numerals “TG”, “SG”, and “RG”, for the convenience of explanation, and the gate (or the gate electrode) of the driving transistor DX is assigned with reference numeral “SF”.

According to some example embodiments of the present inventive concepts, when the four pixels illustrated are the first to fourth pixels PX1, PX2, PX3, and PX4, the first to fourth pixels PX1, PX2, PX3, and PX4 may be arranged in a 2×2 matrix form. According to some example embodiments, the first pixel PX1 and the second pixel PX2 include the transfer gate TG and the driving gate SF, and may share the driving gate SF. The third pixel PX3 may include the transfer gate TG and the reset gate RG, and the fourth pixel PX4 may include the transfer gate TG and the selection gate SG. In some example embodiments, the placement of the transfer gate TG, the driving gate SF, the reset gate RG, and the selection gate SG in the four pixels is provided only for the illustrative purpose. However, the transfer gate TG, the driving gate SF, the reset gate RG, and the selection gate SG in the four pixels may be differently placed. For example, the transfer gate TG, the driving gate SF, the reset gate RG, and the selection gate SG may all be disposed in each pixel.

According to some example embodiments, the first pixel PX1 and the second pixel PX2 may share the driving transistor DX (e.g., may share a plurality of driving transistors, including for example the first to fourth driving transistors DX1, DX2, DX3, and DX4). In some example embodiments, the driving transistor DX may be provided to cross the first pixel PX1 and the second pixel PX2 when viewed in a plan view. In some example embodiments, the device isolation layer 131 may have (e.g., may define) a cutout part 131ct formed by removing a portion of the device isolation layer 131 between the first pixel PX1 and the second pixel PX2 (e.g., such that the cutout part 131ct omits the device isolation layer 131 in a region between the first pixel PX1 and the second pixel PX2), and the driving transistor DX may be disposed in the cutout part 131ct. However, the layout including the placement of the driving transistors DX is not limited thereto, and the driving transistor DX may be variously disposed depending on the position of the cutout part 131ct. For example, the cutout part 131ct of the device isolation layer 131 may be disposed in one of opposite ends of the device isolation layer 131 between the first pixel PX1 and the second pixel PX2 as illustrated in drawings. According to some example embodiments, the cutout part 131ct may be disposed at the central portion of the device isolation layer 131 between the first pixel PX1 and the second pixel PX2.

According to some example embodiments of the present inventive concepts, the transfer gate TG may constitute the transfer transistor TX, and the transfer transistor TX may be configured to transfer the charges, which are generated in the photodiode PD, to the floating diffusion region FD. The reset gate RG may constitute the reset transistor RX, and the reset transistor RX may be configured to periodically reset the charges stored in the floating diffusion region FD. The driving gate SF may constitute the driving transistor DX, and the driving transistor DX may serve as a source follower buffer amplifier, and may be configured to buffer a signal resulting from the charges charged in the floating diffusion region FD. The selection gate SG may constitute the selection transistor SX, and the selection transistor SX may perform switching and addressing to select the pixel PX.

The transfer gate TG may be provided as a buried gate electrode. A buried transfer driving gate electrode may be disposed inside a transfer gate trench extending from the first surface 110F of the semiconductor substrate 110 toward the inner portion of the semiconductor substrate 110. A gate insulating layer GI may be conformally disposed on the inner wall of the transfer gate trench, and the buried transfer driving gate electrode may be disposed on the gate insulating layer GI to be filled in the transfer gate trench. However, the form, in which the transfer gate is provided, is not limited thereto. For example, the transfer gate may be provided in a planar form rather than a buried form. According to some example embodiments of the present inventive concepts, the buried transfer driving gate electrode may include at least one of doped polysilicon, metal, a metal silicide, a metal nitride, or a metal-containing film. The gate insulating layer GI may include a silicon oxide or a metal oxide.

Pixel transistors, such as the driving transistor DX, the reset transistor RX, and the selection transistor SX, except for the transfer transistor TX, may be finFET type transistors. In particular, according to some example embodiments of the present inventive concepts, the driving transistor DX may include a plurality of driving transistors connected in parallel, and the plurality of driving transistors may form the finFET type transistor having a multi-finger structure.

For example, the driving transistor DX may include four driving transistors (that is, the first to fourth driving transistors DX1, DX2, DX3, and DX4), and the first to fourth driving transistors DX1, DX2, DX3, and DX4 may be arranged in a multi-finger structure.

According to some example embodiments of the present inventive concepts, the driving transistor DX (e.g., the first to fourth driving transistors DX1, DX2, DX3, and DX4) may include the fin-type active region FN and the driving gate electrode SF disposed on the fin-type active region FN.

The driving gate electrode SF may be shared by the plurality of driving transistors DX, for example such that the plurality of driving transistors (e.g., the first to fourth driving transistors DX1, DX2, DX3, and DX4) include separate, respective portions (e.g., branch parts GEB) of the driving gate electrode SF that are on (e.g., in at least the third direction D3) one or more surfaces of separate, respective channel regions corresponding to the separate, respective driving transistors (e.g., channel regions CH1, CH2, CH3, and CH4, respectively). The driving gate electrode SF includes a plurality of branch parts GEb corresponding to the driving transistors DX (e.g., corresponding to separate, respective driving transistors of the first to fourth driving transistors DX1, DX2, DX3, and DX4), and a main body part GEa which is formed integrally with the branch parts GEb without being separated from the branch parts GEb to connect the branch parts GEb to each other, for example such that the main body part GEa and the branch parts GEb are defined by separate, respective portions of a single, unitary piece of material. The branch parts GEb may include a first branch part GEb1 corresponding to the first driving transistor DX1, a second branch part GEb2 corresponding to the second driving transistor DX2, a third branch part GEb3 corresponding to the third driving transistor DX3, and a fourth branch part GEb4 corresponding to the fourth driving transistor DX4. Since the driving gate electrodes SF have an integral form without being separated from each other and are shared as the gates of the four driving transistors DX, a bypass electrical connection based on a separate contact CT and a separate wiring is not required. Accordingly, the parasitic capacitance resulting from the separate wiring between gates of the driving transistors may be reduced or minimized. Accordingly, the image sensor may be prevented from deteriorated due to the parasitic capacitance, or such deterioration may be reduced or minimized, and thus the functionality (e.g., image generating functionality, image generating performance, etc.) of the image sensor may be improved, for example the functionality may be improved without limiting miniaturization of the image sensor, or the image sensor may be further miniaturized without compromising the image generating performance of the image sensor, based on the image sensor including the plurality of driving transistors DX and a driving gate electrode SF that may be shared by the plurality of driving transistors DX according to some example embodiments.

The fin-type active region FN is overlapped with the driving gate electrode SF (particularly, the branch part GEb of the driving gate electrode) while longitudinally extending. The fin-type active region FN includes first to fourth channel regions CH1, CH2, CH3, and CH4 disposed under the first to fourth branch parts GEb1, GEb2, GEb3, and GEb4, respectively. The first to fourth channel regions CH1, CH2, CH3, and CH4 are sequentially arranged within the fin-type active region FN and are spaced apart from each other. In some example embodiments, the branch parts GEb are disposed on the first to fourth channel regions CH1, CH2, CH3, and CH4 of the corresponding first to fourth driving transistors DX1, DX2, DX3, and DX4, respectively, and function as driving gate electrodes of the first to fourth driving transistors DX1, DX2, DX3, and DX4. Source-drain regions SD are provided at opposite sides of each of the channel regions.

According to some example embodiments of the present inventive concepts, provided under the branch part GEb, the first channel region CH1 may have a first channel length L1. In addition, the second channel region CH2 may have a second channel length L2. In addition, the third channel region CH3 may have a third channel length L3. In addition, the fourth channel region CH4 may have a fourth channel length L4. Accordingly, the driving transistor DX may be understood as a transistor having a channel length L1+L2+L3+L4 obtained by adding the first to fourth channel lengths L1 to L4 of the first to fourth channel regions CH1 to CH4.

When viewed in a plan view, the plurality of source-drain regions SD may be provided and disposed at opposite sides of each channel region, and may be sequentially disposed in a direction from one end to an opposite end of the fin-type active region FN. The number of the source-drain regions SD may vary depending on the number of channel regions, but at least three source-drain regions SD may be provided. According to some example embodiments, the source-drain region SD may include a first source-drain region SD1 and a second source-drain region SD2 disposed at opposite sides of the first channel region CH1, a third source-drain region SD3 disposed between the second channel region CH2 and the third channel region CH3, a fourth source-drain region SD4 disposed between the third channel region CH3 and the fourth channel region CH4, and a fifth source-drain region SD5 spaced apart from the fourth source-drain region SD4 while interposing the fourth channel region CH4 between the fourth source-drain region SD4 and the fifth source-drain region SD5.

According to some example embodiments of the present inventive concepts, a plurality of driving transistors (that is, two driving transistors adjacent to each other among the first to fourth driving transistors DX1, DX2, DX3, and DX4) may physically share the source-drain region provided between the two driving transistors. In some example embodiments, the wording “physically sharing” may refer to operating in the form of one component through integrally forming without separating, instead of being electrically connected through a separate wiring.

For example, the first driving transistor DX1 may include the first branch part GEb1 serving as the driving gate electrode, the first and second source-drain regions SD1 and SD2 serving as the source and drain region of the first driving transistor DX1. The second driving transistor DX2 may include the second branch part GEb2 serving as the driving gate electrode, and the second and third source-drain regions SD2 and SD3 serving as the source and drain regions of the second driving transistor DX2. As a result, the second source-drain region SD2 may be physically shared by the first and second driving transistors DX1 and DX2. Similarly, the third driving transistor DX3 includes the third branch part GEb3 serving as a driving gate electrode, and the third and fourth source-drain regions SD3 and SD4 serving as source and drain regions of the third driving transistor DX3. The third source-drain region SD3 is physically shared by the second and third driving transistors DX2 and DX3. The fourth driving transistor DX4 includes the fourth branch part GEb4 serving as a driving gate electrode, and the fourth and fifth source-drain region SD4 and SD5 serving as source and drain regions of the fourth driving transistor DX4, and the fourth source-drain region SD4 is physically shared by the third and fourth driving transistors DX3 and DX4. Accordingly, two adjacent driving transistors among the plurality of driving transistors (e.g., DX1 and DX2, DX2 and DX3, DX3 and DX4, etc.) may physically share a particular source-drain region among the source-drain regions that is between the two adjacent driving transistors (e.g., SD2, SD3, or SD4, respectively) such that the particular source-drain region is (e.g., serves as, corresponds to, etc.) a source region or a drain region of each of the two adjacent driving transistors (e.g., the second source-drain region SD2 serves as a source region or a drain region of the first and second driving transistors DX1 and DX2, the third source-drain region SD3 serves as a source region or a drain region of the second and third driving transistors DX2 and DX3, and the fourth source-drain region SD4 serves as a source region or a drain region of the third and fourth driving transistors DX3 and DX4).

According to some example embodiments of the present inventive concepts, each source-drain region SD may function as any one of a source region or a drain region according to a connection relationship between wirings. In some example embodiments, odd-numbered source-drain regions among the source-drain regions SD are connected to the same component, and even-numbered source-drain regions SD among the source-drain regions SD are connected to the same component. Source-drain regions may be “numbered” according to a sequence of the source-drain regions from one side FN-1 of the fin-type active region FN to an opposite side FN-2 of the fin-type active region FN along an extension length of the fin-type active region FN (e.g., along view line B-B′ as shown in FIGS. 4 and 5B). In some example embodiments, odd-numbered source-drain regions among the source-drain regions SD (e.g., along the sequence of source-drain regions SD from one side FN-1 of the fin-type active region FN to an opposite side FN-2 of the fin-type active region FN) correspond to (e.g., serve as) one of a source region or a drain region, and even-numbered source-drain regions SD among the source-drain regions SD correspond to (e.g., serve as) a remaining one of the source region or the drain region. For example, in example embodiments where odd-numbered source-drain regions correspond to a source region, the even-numbered source-drain regions may correspond to a drain region.

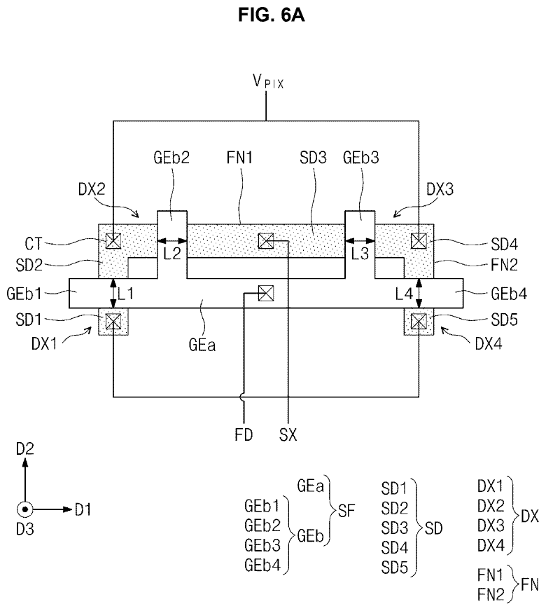

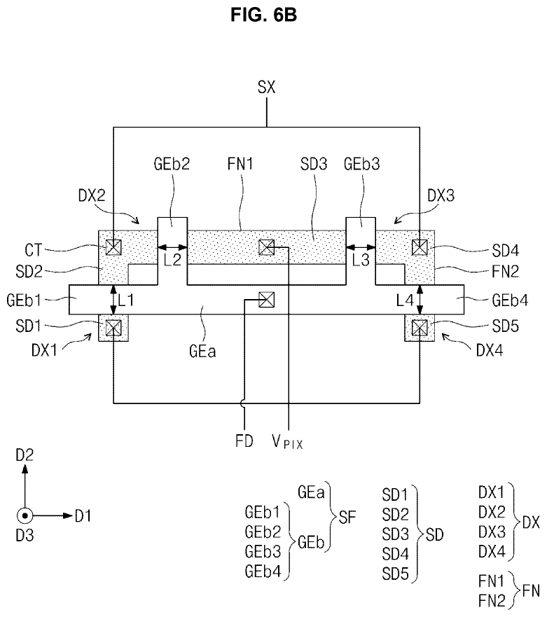

FIGS. 6A and 6B illustrate an electrical connection relationship of the driving transistors DX according to some example embodiments of the present inventive concepts. In the drawings, a portion indicated by a thick solid line refers to a portion connected by a separate wiring through the contact CT.

Referring to FIG. 6A, the first, third, and fifth source-drain regions SD5 may correspond to source regions in each driving transistor DX, and may be connected to the selection transistor SX through a separate wiring such as the contact CT to output an electrical signal through the selection transistor SX. The second and fourth source-drain regions SD2 and SD4 may correspond to drain regions in each driving transistor DX, and may be connected to a power supply through the separate wiring such as the contact CT.

According to some example embodiments, referring to FIG. 6B, the first, third, and fifth source-drain regions SD1, SD3, and SD5 may correspond to drain regions in each driving transistor DX, and may be connected to power through a separate wiring such as the contact CT. The second and fourth source-drain regions SD2 and SD4 may correspond to source regions in each driving transistor DX, and may be connected to the selection transistor SX through a separate wiring such as the contact CT to output an electrical signal through the selection transistor SX.

As described above, the driving gate electrode SF and the first to fifth source-drain regions SD1, SD2, SD3, SD4, and SD5 are connected to other components through the contact CT and the separate wiring to implement one pixel circuit. The driving gate electrode SF is connected to the floating diffusion region FD, and the source-drain region SD corresponding to the source region among the first to fifth source-drain regions SD1, SD2, SD3, SD4, and SD5 is connected to the drain of the selection transistor SX, and the source-drain region SD corresponding to the drain region among the first to fifth source-drain regions SD1, SD2, SD3, SD4, and SD5 is connected to the power supply.

Referring to FIGS. 3 to 6B, according to some example embodiments of the present inventive concepts, the fin-type active region FN may be bent more than once, for example, two or more times when viewed in a plan view. For example, according to some example embodiments, the fin-type active region FN may include a first part FN1 extending in the first direction D1 and a second part FN2 extending in a direction crossing the first direction D1 (e.g., a direction opposite to the second direction D2). For example, according to some example embodiments, the second part FN2 corresponds to a part bent from opposite ends of the first part FN1 while extending in a direction perpendicular to the extension direction of the first part FN1. The fin-type active region FN may be bent (e.g., change extension direction along the extension of the fin-type active region FN) in this manner, once or more times (e.g., at least once), such that the channel regions and the source-drain region SD may be efficiently disposed in a relatively narrow space.

When viewed in a plan view, the driving gate electrode SF may cross the fin-type active region FN while crossing an extension direction of the fin-type active region FN. A portion (e.g., a first portion) of the driving gate electrode SF may cross the fin-type active region FN in the second direction D2 from the first part FN1 of the fin-type active region FN (e.g., the first portion of the driving gate electrode SF may extend in the second direction D2 to cross the first part FN1 of the fin-type active region FN in the third direction D3), and may cross the second part FN2 of the fin-type active region FN in the first direction D1 from the second part FN2 of the fin-type active region FN (e.g., a second portion of the driving gate electrode SF may extend in the first direction D1 to cross the second part FN2 of the fin-type active region FN in the third direction D3). For example, the first branch part GEb1 and the fourth branch part GEb4 of the driving gate electrode SF may cross the fin-type active region FN in the first direction D1 in the second part FN2, and the second branch part GEb2 (e.g., to overlap the second part FN2 in the third direction D3) and the third branch part GEb3 may cross the fin-type active region FN in the second direction D2 in the first part FN1 (e.g., to overlap the first part FN1 in the third direction D3). Accordingly, the first and fourth channel regions CH1 and CH4 corresponding to the first branch part GEb1 and the fourth branch part GEb4 may cross directions of the second branch part GEb2 and the second and third channel regions CH2 and CH3 corresponding to the third branch part GEb3. As shown, separate, respective parts of the driving gate electrode SF (e.g., branch parts GEb1, GEb2, GEb3, and GEb4) overlap one or more parts of the fin-type active region FN (e.g., one of the first or second part FN1 or FN2) in a vertical direction extending perpendicular to the first surface 110F of the semiconductor substrate 110 (e.g., the third direction D3).

When viewed in a cross-sectional view, the fin-type active region FN protrudes in a direction perpendicular to the first surface 110F of the semiconductor substrate 110. The driving gate electrode SF corresponding to each branch part GEb covers the top surface and opposite sidewalls of the fin-type active region FN provided thereunder. Each branch part GEb of the driving gate electrode SF is provided in a direction crossing the fin-type active region FN, and in each branch part GEb, the branch part GEb may be disposed to cover the fin-type active region FN defined between a first trench TCH1 and a second trench TCH2 extending from the first surface 110F of the semiconductor substrate 110 to the inside of the semiconductor substrate 110. The branch part GEb, and thus the driving gate electrode SF, may be disposed on (e.g., may be configured to cover) a top surface FNu, a first sidewall FNs1, and a second sidewall FNs2 of the fin-type active region FN. For example, the branch part GEb, and thus the driving gate electrode SF, may overlap a top surface FNu of the fin-type active region FN in a third direction D3 extending perpendicular to the first surface 110F. For example, the branch part GEb, and thus the driving gate electrode SF, may overlap opposite sidewalls FNs1 and FNs2 of the fin-type active region FN in a first direction D1 and/or a second direction D2 extending parallel to the first surface 110F and thus perpendicular to the third direction D3.

More specifically, the first and second sidewalls FNs1 and FNs2 of the fin-type active region FN may be defined by the first and second trenches TCH1 and TCH2, respectively. Each of the first and second trenches TCH1 and TCH2 may be disposed to extend in the second direction D2, and the top surface of the fin-type active region FN may extend in the second direction D2, between the first and second sidewalls FNs1 and FNs2. The top surface of the fin-type active region FN may be disposed on the same plane serving as the first surface 110F of the semiconductor substrate 110.

The branch part GEb may be disposed to cover the top surface FNu, the first sidewall FNs1, and the second sidewall FNs2 of the fin-type active region FN. For example, each branch part GEb may include a horizontal extension part GEbp, a first vertical extension part GEv1, and a second vertical extension part GEv2. The first vertical extension part GEv1 may be disposed inside the first trench TCH1 to cover (e.g., at least partially overlap in the first direction D1) the first sidewall FNs1 of the fin-type active region FN, and the second vertical extension part GEv2 may be disposed inside the second trench TCH2 to cover (e.g., at least partially overlap in the first direction D1) the second sidewall FNs2 of the fin-type active region FN. The horizontal extension part GEbp may cover the top surface FNu of the fin-type active region FN, and may be connected to the first vertical extension part GEv1 and the second vertical extension part GEv2.

The gate insulating layer GI may be interposed between the branch part GEb and the fin-type active region FN. For example, the gate insulating layer GI may be conformally disposed on the inner walls of the first trench TCH1 and the second trench TCH2, and may extend onto the first surface 110F of the semiconductor substrate 110.

The fin-type active region FN may include a channel region corresponding to each driving transistor DX and the source-drain regions SD provided at opposite sides of the channel region. According to some example embodiments of the present inventive concepts, the driving transistor DX may include the first to fourth driving transistors DX1, DX2, DX3, and DX4. In some example embodiments, the channel regions CH1, CH2, CH3, and CH4 are provided in the fin-type active region FN.

According to some example embodiments of the present inventive concepts, the first to fifth source-drain regions SD1, SD2, SD3, SD4, and SD5 may have the first conductivity type. For example, the first to fifth source-drain regions SD1, SD2, SD3, SD4, and SD5 may be regions doped with n-type impurities.

According to some example embodiments of the present inventive concepts, the fin-type active region FN may be formed by forming the first trench TCH1 and the second trench TCH2 having specific heights in a direction perpendicular to the first surface 110F of the semiconductor substrate 110. As illustrated in FIG. 4, the first and second sidewalls FNs1 and FNs2 of the fin-type active region FN extend in the third direction D3, and the fin-type active region FN has a specific width, which is substantially uniform with respect to the entire height of the first and second sidewalls FNs1 and FNs2. However, a width of upper portions of the first and second trenches TCH1 and TCH2 may be less than a width of lower portions of the first and second trenches TCH1 and TCH2 depending on attributes of an etching process applied to forming the first and second trenches TCH1 and TCH2. In some example embodiments, the first and second sidewalls FNs1 and FNs2 may extend at a tilting angle to become closer to each other upward of the fin-type active region FN, and the width of the top surface of the fin-type active region FN may be less than the width of the bottom surface of the fin-type active region FN.

According to some example embodiments of the present inventive concepts, the driving gate electrode SF may include at least one of doped polysilicon, metal, a metal silicide, a metal nitride, or a metal-containing film.

A lower barrier region 113 may be disposed between the fin-type active region FN and the photodiode PD. The lower barrier region 113 may be a region heavily doped with p-type impurities, and may function as a barrier which prevents electrons from moving from the photodiode PD to the fin-type active region FN, or from the fin-type active region FN to the photodiode PD. According to some example embodiments of the present inventive concepts, the lower barrier region 113 may be disposed over the entire region of the pixel transistor to be vertically overlapped with the fin-type active region FN and the driving gate electrode SF and be connected to the device isolation layer 131.

Although not illustrated separately, a lateral barrier region may be disposed around the fin-type active region FN. The lateral barrier region may be a region heavily doped with p-type impurities. According to some example embodiments, the lateral barrier region may include an insulating film having a shallow trench isolation structure for complete electrical blocking and formed of an insulating material.

A buried insulation layer 123 may be disposed on the first surface 110F of the semiconductor substrate 110. The buried insulation layer 123 may cover the ground region GND, the floating diffusion region FD, the shallow device isolation layer 133, the buried transfer driving gate electrode SF, or the driving gate electrode SF. The buried insulation layer 123 may be formed to have a height sufficient to cover the top surface of the driving gate electrode SF.

According to some example embodiments of the present inventive concepts, the buried insulation layer 123 may include a silicon nitride and a silicon oxynitride. According to some embodiments, the buried insulation layer 123 may be formed in a stack structure of two or more layers. According to some example embodiments, an etching stop layer (not illustrated) may be interposed between the buried insulation layer 123 and the first surface 110F of the semiconductor substrate 110, and the etching stop layer may include a material having etch selectivity with respect to the buried insulation layer 123.

The contact CT formed through the buried insulation layer 123 may be disposed on the first surface 110F of the semiconductor substrate 110. For example, the contact CT may be formed through the buried insulation layer 123 to be electrically connected to the source-drain regions SD, the buried transfer driving gate SF, the driving gate SF, the selection gate SG, and the reset gate RG. As shown, the contact CT may include a via portion TH extending through the thickness of the buried insulation layer to contact the transfer gate TG.

An upper wiring structure 125 may be provided on the buried insulation layer 123. The upper wiring structure 125 may include a conductive line and an insulating layer, and may be formed in a stack structure of a plurality of layers. The conductive line may include at least one of polysilicon, metal, a metal silicide, a metal nitride, or a metal-containing film doped or undoped with impurities. For example, the conductive line may include tungsten, aluminum, copper, tungsten silicide, titanium silicide, tungsten nitride, titanium nitride, doped polysilicon, or the like. The insulating layer may include an insulating material such as a silicon oxide, a silicon nitride, a silicon oxynitride, etc.

A backside insulating layer 121 may be disposed on the second surface 110R of the semiconductor substrate 110. The backside insulating layer 121 may be disposed on substantially the entire area of the second surface 110R of the semiconductor substrate 110, and may be in contact with the top surface of the device isolation layer 131 disposed in the same level as the second surface 110R of the semiconductor substrate 110. According to some example embodiments of the present inventive concepts, the backside insulating layer 121 may include a metal oxide such as a hafnium oxide, an aluminum oxide, or a tantalum oxide. According to some example embodiments, the backside insulating layer 121 may include an insulating material, such as a silicon oxide, a silicon nitride, a silicon oxynitride, a low dielectric constant material, etc.

A color filter CF and a micro-lens ML may be disposed on the backside insulating layer 121.

The color filter CF may be disposed in each pixel PX on the second surface 110R of the semiconductor substrate 110. For example, the color filter CF may be provided at a position corresponding to the photodiode PD. Each of the color filter CF may include any one of a red filter, a blue filter, and a green filter, but the present inventive concepts are not limited thereto. For example, the color filter CF may include filters having different colors. Color filters CF may form color filter arrays. For example, the color filters CF may form arrays which are arranged in the first and second directions D1 and D2 when viewed in a plan view.

The micro-lens ML may be disposed on the second surface 110R of the semiconductor substrate 110, for example, on the color filter CF. The micro-lens ML may be transparent and may transmit light. The micro-lens ML may include an organic material such as a polymer. For example, the micro-lens ML may include a photoresist material or a thermosetting resin.

According to some example embodiments of the present inventive concepts, a plurality of pixels adjacent to each other among the plurality of pixels may share one micro-lens ML. For example, two pixels adjacent to each other in the first and/or second directions D1 and/or D2 (that is, the first and second pixels PX1 and PX2) may share one micro-lens ML, for example such that the one micro-lens ML may at least partially overlap the two pixels in the third direction D3. In some example embodiments, four pixels adjacent to each other and arranged in a 2×2 matrix form, in other words, the first to fourth pixels PX1, PX2, PX3, and PX4, may share one micro-lens ML. According to some example embodiments of the present inventive concepts, auto-focusing may be implemented by sharing the micro-lens ML with two or more pixels. Auto-focusing may be implemented using phase differences occurring in pixels adjacent to each other.

According to some example embodiments of the present inventive concepts, pixels corresponding to one micro-lens ML may be the first and second pixels PX1 and PX2, and the first and second pixels PX1 and PX2 may share one micro-lens ML and include separate photodiodes PD, respectively. Accordingly, separate incident light is introduced into the first and second pixels PX1 and PX2, respectively, and phase differences of light provided to the first and second pixels PX1 and PX2 may be obtained. By measuring the phase difference of light incident on one pixel PX, the image sensor may be autofocused. When each pixel PX is not used for autofocusing, an image signal may be obtained, and in some example embodiments, a method of collecting information on the first and second pixels PX1 and PX2 may be used. As described above, the image sensor according to some example embodiments of the present inventive concepts may use the pixels PX for autofocusing and obtaining an image signal, and if necessary, only some pixels may be used for autofocusing and the remaining pixels may be used to obtain an image signal.

Although not illustrated, a protective layer may be provided on the micro-lens ML, and may include an organic material and/or an inorganic material. According to some example embodiments, the protective layer may include a silicon-containing material such as a silicon oxide, a silicon nitride, a silicon oxynitride, a silicon carbide, a silicon carbon oxide, a silicon carbon nitride, and/or a silicon oxycarbonitride. According to some example embodiments, the protective layer may include an aluminum oxide, a zinc oxide, and/or a hafnium oxide. The protective layer may have insulating properties, but the present inventive concepts are not limited thereto. The protective layer may transmit light.

According to the image sensor having the above-described structure, a circuit of the image device may be stably implemented while a 2-stack structure including the first structure and the second structure is employed. The details thereof will be described later.

According to some example embodiments of the present inventive concepts, other pixel transistors (e.g., a reset transistor, a driving transistor, or a selection transistor). May be formed together with the transfer transistor in one substrate (e.g., semiconductor substrate) having the first structure including a photodiode formed therein. For example, transistors may be formed together in a pixel by forming the transfer transistor in any one pixel, and forming the transfer transistor and the driving transistor in another pixel. The transistors are disposed to be spaced apart from each other in the horizontal direction within the pixel. However, as the degree of integration of the image sensor is increased, the size of the unit pixel is decreased, and the size of each component of the pixel transistors is decreased. Accordingly, the leak current or the read noise of the pixel circuit is caused through the pixel transistor. In an image device having a 2-PD structure which drives two pixels in the same form as one pixel for autofocusing, the space within the pixel is inevitably smaller. In some example embodiments, a leakage current or read noise becomes severer.

In particular, when a photodiode, other logic circuits, and/or pixel transistors are implemented in three or more semiconductor substrates (e.g., a 3-stack structure), the space for implementing the pixel transistors may be sufficiently ensured. However, when a photodiode and pixel transistors are implemented in two semiconductor substrates (that is, a 2-stack structure), it is difficult to secure sufficient space for arranging pixel transistors.

In particular, when a photodiode and a pixel structure are formed in the first structure, when viewed in a plan view, the space in the pixel of the semiconductor substrate is confined and the shallow device isolation layer is provided in the semiconductor substrate. Accordingly, it is difficult to sufficiently ensure the length and the width of the channel of the transistor.

In addition, when viewed in a cross-section view, it may be difficult to sufficiently secure the distance for electrical isolation between the photodiode disposed at the lower portion of the semiconductor substrate and the transistor disposed at the upper portion of the semiconductor substrate.

In addition, the photodiode is formed by doping a specific impurity (e.g., an n-type dopant) into the semiconductor substrate. When the pixel transistors are arranged in a narrow semiconductor substrate without sufficient space, impurities from the photodiode move to a channel of the transistor disposed at the upper portion of the photodiode, thereby causing the undesirable channel doping. To prevent such channel doping, the transistors must be sufficiently spaced apart from the photodiode. Accordingly, the finFET-type transistor may have constraints in height of the fin part to sufficiently ensure the distance from the photodiode. Accordingly, when the height of the fin part is limited, the width or the length of the channel region may be largely increased.

According to some example embodiments of the present inventive concepts, the image device employs a finFET structure to ensure a channel region of transistors, (especially, a driving transistor) in a confined pixel region. in some example embodiments, a multi-finger structure having a plurality of transistors connected to each other in parallel is employed, thereby easily forming pixel transistors including a channel region having a sufficient width and a sufficient length in a narrow pixel space. In other words, the width of the channel may be increased by arranging the driving gate electrode to cover the top surface, the first sidewall, and the second sidewall of the fin-type active region using the finFET structure, and the length of the channel may be increased by arranging the plurality of transistors in parallel using a multi-finger structure. Accordingly, even if the size of each individual transistor is small, the width and length of the larger channel region may be ensured, and the control capability of the gate for the channel may be improved. Accordingly, the read noise may be reduced and leakage current of the transistor may be reduced, and thus the functionality (e.g., image generating functionality, image generating performance, etc.) of the image sensor may be improved based on including the multi-finger structure to configure the image sensor to reduce, minimize, or prevent noise in the electrical signal output of the image sensor.

Accordingly, according to some example embodiments of the present inventive concepts, the image sensor may increase the width of the channel and the length of the driving transistor through the above-described structure. In addition, accordingly, the image sensor may reduce noise included in the output signal, and thus the functionality (e.g., image generating functionality, image generating performance, etc.) of the image sensor may be improved.

According to some example embodiments of the present inventive concepts, the image sensor may be changed into various forms without deviating from the spirit of the present inventive concepts. For example, according to some example embodiments of the present inventive concepts, the structure and number of driving transistors of the image sensor may be changed.

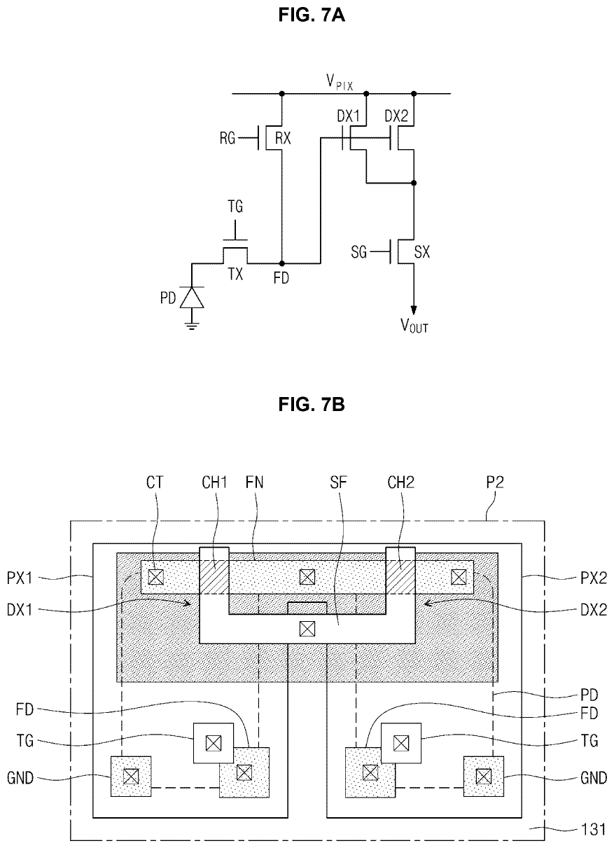

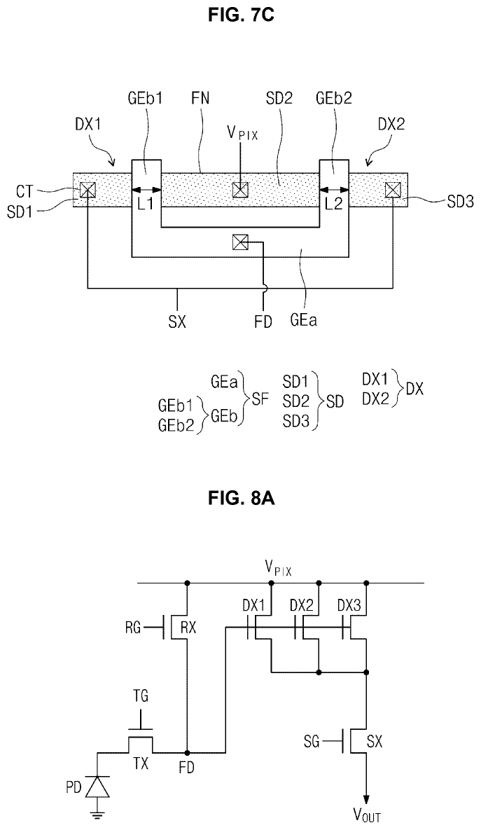

FIG. 7A is an equivalent circuit diagram of one pixel in an image device according to some example embodiments of the present inventive concepts, FIG. 7B is a plan view illustrating a part of the pixel according to some example embodiments and a part corresponding to a part P2 of FIG. 4 according to some example embodiments of the present inventive concepts, and FIG. 7C illustrates an electrical connection relationship of the driving transistor illustrated in FIG. 7B according to some example embodiments of the present inventive concepts.

The following description will be made while focusing on the difference from the above-described example embodiments to avoid redundancy, and the description about the substantially same component will be omitted.

Referring to FIGS. 7A to 7C, according to some example embodiments of the present inventive concepts, the driving transistor DX may include two driving transistors (i.e., first and second driving transistors DX1 and DX2) and the first and second driving transistors DX1 and DX2 may be disposed in a multi-finger structure. Each drain of the first and second driving transistors DX1 and DX2 may be connected to the power supply voltage V_{PIX} and may be connected in parallel to each other (e.g., connected in parallel to at least the power supply voltage V_{PIX}.

According to some example embodiments of the present inventive concepts, the driving gate electrode SF may be shared by the first and second driving transistors DX1 and DX2. The driving gate electrode SF may include the first branch part GEb1 corresponding to the first driving transistor DX1, the second branch part GEb2 corresponding to the second driving transistor DX2, and the main body part GEa integrally formed without separation while connecting the first branch part GEb1 and the second branch part GEb2, for example such that the main body part GEa and the first and second branch parts GEb1 and GEb2 are defined by separate, respective portions of a single, unitary piece of material.

The fin-type active region FN is overlapped with the driving gate electrode SF (especially, the first and second branch parts GEb1 and GEb2 of the driving gate electrode SF) while longitudinally extending. According to some example embodiments, the fin-type active region FN may be provided in the form of a straight line which is not bent. However, the shape of the fin-type active region FN is not limited thereto. For example, the fin-type active region FN may be bent one or more times depending on the size and shape of the region for the fin-type active region FN.

The first channel region CH1 and the second channel region CH2 may be provided under the first branch part GEb1 and the second branch part GEb2, respectively. The source-drain regions SD are provided at opposite sides of the first and second channel regions CH1 and CH2, respectively, and the first to third source-drain regions SD1, SD2, and SD3 are sequentially provided from one end of the fin-type active region FN toward an opposite end of the fin-type active region FN.

The first channel region CH1 and the second channel region CH2 may have first and second channel lengths L1 and L2, respectively. Accordingly, according to some example embodiments, the first and second driving transistors DX1 and DX2 may be understood as one driving transistor DX having channel lengths (L1+L2) obtained by adding the channel length of the first channel region CH1 and the channel length of the second channel region CH2.

According to some example embodiments of the present inventive concepts, the first and second driving transistors DX1 and DX2 may physically share the source-drain region SD provided between the first and second driving transistors DX1 and DX2. According to some example embodiments, the second source-drain region SD2 is physically shared by the first and second driving transistors DX1 and DX2.

According to some example embodiments of the present inventive concepts, each source-drain region SD may function as any one of a source region or a drain region depending on a connection relationship between wirings. According to some example embodiments, the first source-drain region SD1 and the third source-drain region SD3 of the source-drain region SD may correspond to source regions and may be connected to the drain of the selection transistor SX. The second source-drain region SD2 may correspond to a drain region, and receive a power supply voltage. The driving gate electrode SF is connected to the floating diffusion region FD through a separate wiring while passing through the contact CT.

Although not illustrated, according to some example embodiments of the present inventive concepts, the first source-drain region SD1 and the third source-drain region SD3 of the source-drain region SD may correspond to drain regions. In some example embodiments, the power supply voltage may be applied to the first source-drain region SD1 and the third source-drain region SD3. The second source-drain region SD2 may correspond to the source region, and may be connected to the drain of the selection transistor SX.

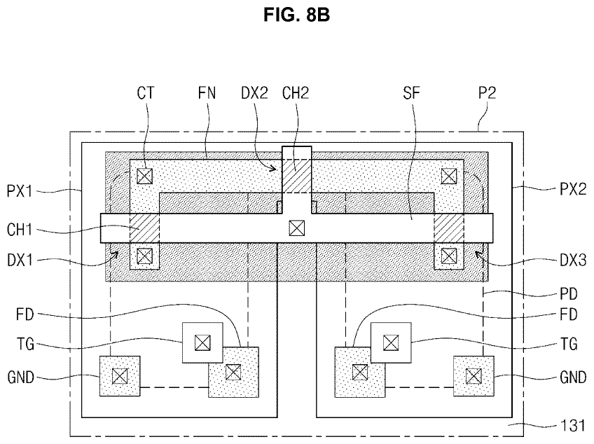

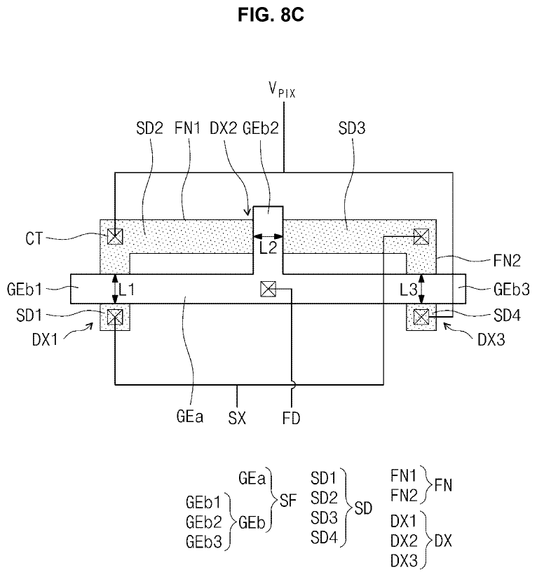

FIG. 8A is an equivalent circuit diagram of one pixel in an image device according to some example embodiments of the present inventive concepts, FIG. 8B is a plan view illustrating a part of the pixel according to some example embodiments and a part corresponding to a part P2 of FIG. 4 according to some example embodiments of the present inventive concepts, and FIG. 8C illustrates an electrical connection relationship of the driving transistor illustrated in FIG. 8B according to some example embodiments of the present inventive concepts.

Referring to FIGS. 8A to 8C, the driving transistor DX may include three driving transistors (that is, the first to third driving transistors DX1, DX2, and DX3), and the first to third driving transistors DX1, DX2, and DX3 may be disposed in a multi-finger structure. Each drain of the first and second driving transistors DX1 and DX2 may be connected to the power supply voltage V_{PIX} and may be connected to each other in parallel.

The driving gate electrode SF may be shared by the first to third driving transistors DX1, DX2, and DX3. The driving gate electrode SF includes the first to third branch parts GEb1, GEb2, and GEb3 corresponding to the first to third driving transistors DX1, DX2, and DX3, respectively, and the main body part GEa formed integrally with the first to third branch parts GEb1, GEb2, and GEb3, without being separated from the first to third branch parts GEb1, GEb2, and GEb3, for example such that the main body part GEa and the first to third branch parts GEb1, GEb2, and GEb3 are defined by separate, respective portions of a single, unitary piece of material.

The fin-type active region FN may be overlapped with the first to third branch parts GEb1, GEb2, and GEb3 of the driving gate electrode SF while longitudinally extending, and may be bent one or more times. The fin-type active region FN may be bent two times as illustrated in drawings. Accordingly, the fin-type active region FN may include the first part FN1 longitudinally extending in the first direction D1 and the second part FN2 longitudinally extending in the second direction D2 from the end portion of the first part FN1. The first and third branch parts GEb1 and GEb3 among the first to third branch parts GEb1, GEb2, and GEb3 may be overlapped with the second part FN2 while crossing the second part FN2. The second branch part GEb2 may be overlapped with the first part FN1 while crossing the first part FN1.

The first to third channel regions CH1 to CH3 may be provided under the first to third branch parts GEb1 to GEb3, respectively. Source-drain regions SD are provided at opposite sides of each of the first to third channel regions CH1, CH2, and CH3, and the first to fourth source-drain regions SD1, SD2, SD3, and SD4 are sequentially disposed from one end of the fin-type active region FN toward an opposite end of the fin-type active region FN.

According to some example embodiments, the first to third channel regions CH1 to CH3 may have the first to third channel lengths L1, L2, and L3, respectively. Accordingly, according to some example embodiments, the first to third driving transistors DX1, DX2, and DX3 may be understood as one driving transistor DX having a channel length (L1+L2+L3) obtained by adding the channel lengths of the first to third channel regions CH1 to CH3.

According to some example embodiments of the present inventive concepts, the first to third driving transistors DX1, DX2, and DX3 may physically share the source-drain region SD provided between two adjacent driving transistors. According to some example embodiments, the second source-drain region SD2 is physically shared by the first and second driving transistors DX1 and DX2, and the second source-drain region SD2 is physically shared by the second and third driving transistors DX2 and DX3.

According to some example embodiments of the present inventive concepts, each source-drain region SD may function as any one of a source region or a drain region depending on the connection relationship between wirings. According to some example embodiments, the first source-drain region SD1 and the third source-drain region SD3 of the source-drain region SD correspond to the source region and may be connected to the drain of the selection transistor SX. The second source-drain region SD2 and the fourth source-drain region SD4 may correspond to drain regions, and receive the power supply voltage V_{PIX}. The driving gate electrode SF is connected to the floating diffusion region FD through the separate wiring while passing through the contact CT.

Although not illustrated, according to some example embodiments of the present inventive concepts, the first source-drain region SD1 and the third source-drain region SD3 of the source-drain region SD may correspond to drain regions, and may receive the power supply voltage. The second source-drain region SD2 and the fourth source-drain region SD4 may correspond to source regions, and may be connected to the drain of the selection transistor SX.

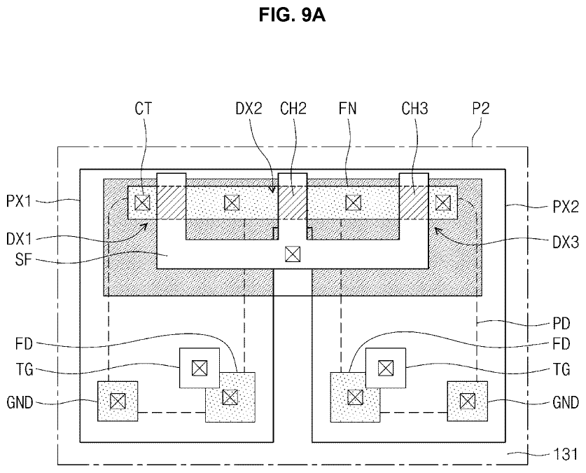

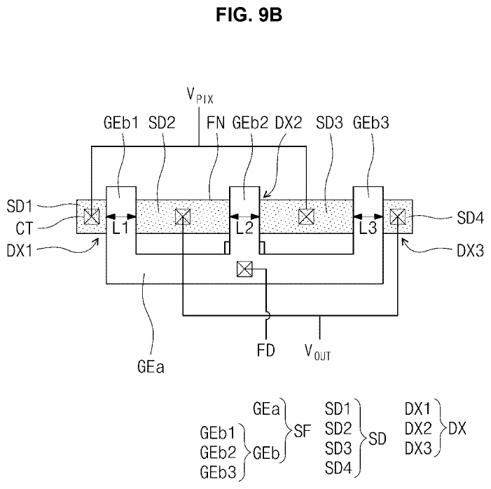

FIG. 9A is a plan view illustrating a part of the pixel according to some example embodiments, and a part corresponding to P2 of FIG. 4 according to some example embodiments of the present inventive concepts, and FIG. 9B illustrates an electrical connection relationship of the driving transistor illustrated in FIG. 9A according to some example embodiments of the present inventive concepts.

Referring to FIGS. 9A to 9B, the driving transistor DX may include three driving transistors DX (that is, the first to third driving transistors DX1, DX2, and DX3), and the first to third driving transistors DX1, DX2, and DX3 may be disposed in a multi-finger structure. Each drain of the first and second driving transistors DX1 and DX2 may be connected to the power supply voltage V_{PIX} and may be connected to each other in parallel.

The driving gate electrode SF may be shared by the first to third driving transistors DX1, DX2, and DX3. The driving gate electrode SF includes the first to third branch parts GEb1, GEb2, and GEb3 corresponding to the first to third driving transistors DX1, DX2, and DX3, respectively, and the main body part GEa integrally formed with the first to third branch parts GEb1, GEb2, and GEb3 without being separated from the first to third branch parts GEb1, GEb2, and GEb3 for example such that the main body part GEa and the first to third branch parts GEb1, GEb2, and GEb3 are defined by separate, respective portions of a single, unitary piece of material. The first to third branch parts GEb1 to GEb3 may all extend in the same direction, for example, in the second direction D2. The main body part GEa may extend in the first direction D1 crossing the second direction D2, and may be connected at one end portions of the first to third branch parts GEb1, GEb2, and GEb3.

The fin-type active region FN may be overlapped with the driving gate electrode SF (particularly, the first to third branch parts GEb1, GEb2, and GEb3 of the driving gate electrode SF) and may longitudinally extend in the first direction D1 without being bent.

The first channel region CH1 to the third channel region CH3 may be provided under the first branch part GEb1 to the third branch part GEb3, respectively. Source-drain regions SD may be provided at opposite sides of each of the first to third channel regions CH1, CH2, and CH3, and the first to fourth source-drain regions SD1, SD2, SD3, and SD4 may be sequentially disposed from one end of the fin-type active region FN toward an opposite end of the fin-type active region FN.

According to some example embodiments, the first to third branch parts GEb1, GEb2, and GEb3 cross the fin-type active region FN in the second direction D2. Accordingly, the first to third channel regions CH1, CH2, and CH3 under the first to third branch parts GEb1, GEb2, and GEb3 are also formed in the same direction.

The first to third channel regions CH1 to CH3 may have first to third channel lengths L1 to L3, respectively. Accordingly, according to some example embodiments, the first to third driving transistors DX1, DX2, and DX3 may be understood as one driving transistor DX having a channel length (L1+L2+L3) obtained by adding the channel lengths of the first to third channel regions CH1 to CH3.

According to some example embodiments of the present inventive concepts, the first to third driving transistors DX1, DX2, and DX3 may physically share the source-drain region SD provided between two adjacent driving transistors DX. According to some example embodiments, the second source-drain region SD2 is physically shared by the first and second driving transistors DX1 and DX2, and the second source-drain region SD2 is physically shared by the second and third driving transistors DX2 and DX3.

According to some example embodiments of the present inventive concepts, each source-drain region SD may function as one of a source region and a drain region depending on the connection relationship between wirings. According to some example embodiments, the first source-drain region SD1 and the third source-drain region SD3 of the source-drain region SD may correspond to source regions and may be connected to the selection transistor SX. The second source-drain region SD2 and the fourth source-drain region SD4 may correspond to drain regions, and may receive the power supply voltage V_{PIX}. The driving gate electrode SF is connected to the floating diffusion region FD through a separate wiring through the contact CT.

Although not illustrated, according to some example embodiments of the present inventive concepts, the first source-drain region SD1 and the third source-drain region SD3 of the source-drain region SD may correspond to drain regions. In some example embodiments, the power supply voltage may be applied to the first source-drain region SD1 and the third source-drain region SD3. The second source-drain region SD2 and the fourth source-drain region SD4 may correspond to source regions, and may be connected to the drain of the selection transistor SX.

As described above, according to some example embodiments of the present inventive concepts, a plurality of driving transistors are connected in parallel, and are connected to components except for the driving transistors through separate wirings. However, the present inventive concepts are not limited thereto. For example, the driving transistors may be directly connected to different components (e.g., a selection transistor), through the source-drain region.

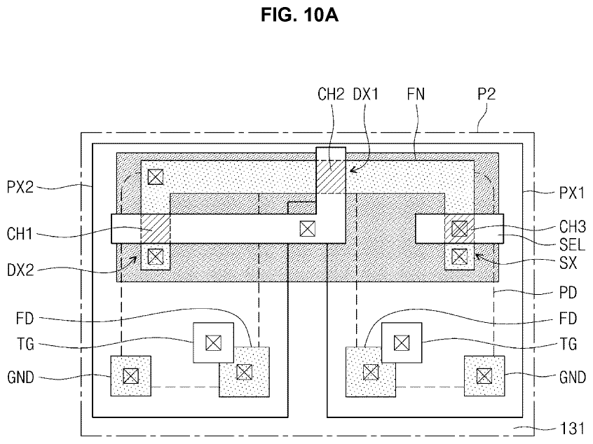

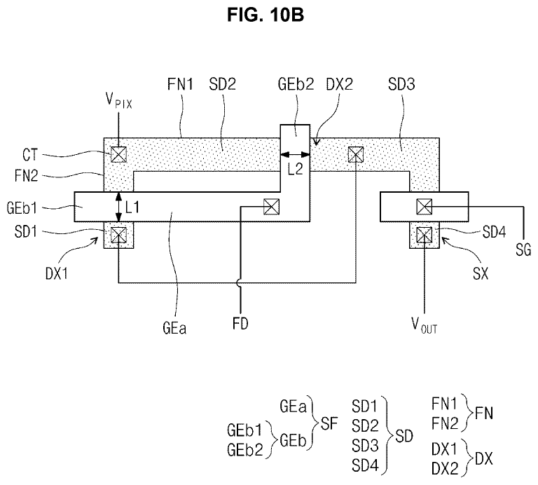

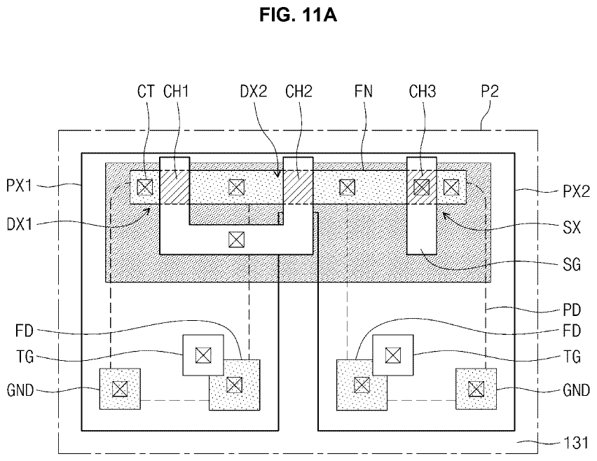

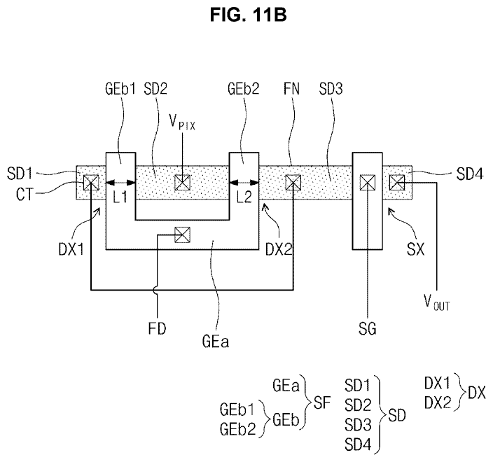

FIG. 10A is a plan view illustrating a part of the pixel corresponding to part P2 of FIG. 4 according to some example embodiments of the present inventive concepts, and FIG. 10B is a view illustrating an electrical connection relationship between the driving transistor and the selection transistor illustrated in FIG. 10A according to some example embodiments of the present inventive concepts. FIG. 11A is a plan view illustrating a part of the pixel corresponding to part P2 of FIG. 4 according to some example embodiments of the present inventive concepts, and FIG. 11B is a view illustrating the electrical connection relationship of the driving transistor illustrated in FIG. 11A according to some example embodiments of the present inventive concepts.

Referring to FIGS. 10A, 10B, 11A, and 11B, the driving transistor DX may include a plurality of transistors, for example, two driving transistors, which are the first and second driving transistors DX1 and DX2, and the first and second driving transistors DX1 and DX2 are disposed in a multi-finger structure. In addition, the selection transistor SX is provided to be adjacent to the first and second driving transistors DX1 and DX2.

According to some example embodiments, the placement of the driving transistor DX and the selection transistor SX may be provided in a form similar to that of the driving transistor DX illustrated in FIGS. 8A to 8C. However, some example embodiments has a difference from FIGS. 8A to 8C illustrating that all branch parts GEb of the driving gate electrode SF are connected to each other in the driving transistor as illustrated in FIGS. 8A to 8C to serve as one driving gate electrode SF, in that one of the branches GEb of the driving gate electrode SF is separated from the main body part GEa instead of being connected to the main body part GEa to function as a separate selection gate SG which receives a selection signal.

More specifically, the driving gate electrode SF of the driving transistor DX may be shared by the first and second driving transistors DX1 and DX2, and the driving gate electrode SF has the first branch part GEb1 and the second branch part GEb2, and is connected to the main body part GEa. The selection gate electrode SG is disposed to be spaced apart from the driving gate electrode SF of the driving transistor DX.

According to some example embodiments of the present inventive concepts, the first and second driving transistors DX1 and DX2 may include the fin-type active region FN and the driving gate electrode SF disposed on the fin-type active region FN. The selection transistor SX may include the fin-type active region FN and the selection gate electrode SG disposed on the fin-type active region FN. In some example embodiments, the fin-type active region FN is provided in one integrated form corresponding to the driving transistor DX and the selection transistor SX. The selection transistor SX may include a particular channel region (e.g., CH3 as shown in FIG. 11A) of the fin-type active region FN and particular source-drain regions (e.g., SD3 and SD4 as shown in FIG. 11B) among the source-drain regions SD of the fin-type active region FN at opposite sides of the particular channel region. The placement relationship between the first and second driving transistors DX1 and DX2 and the selection transistor SX may be variously modified depending on the placement of the fin-type active region FN and the gate electrodes as illustrated in FIGS. 10A, 10B, 11A, and 11B.

The fin-type active region FN is overlapped with the first and second branch parts GEb1 and GEb2 of the driving gate electrode SF and the selection gate electrode SG while longitudinally extending. The fin-type active region FN may be bent one or more times, as illustrated in FIG. 10A, or may not be bent as illustrated in FIG. 11A.

When the fin-type active region is bent twice as illustrated in FIG. 10A, the fin-type active region FN may include the first part FN1 extending in the first direction D1, and the second part FN2 bent from the end of the first part FN1 to extend in the second direction D2. The first branch part GEb1 of the first to second branch parts GEb1 to GEb2 of the driving gate electrode SF may cross and be overlapped with the second part FN2 which is bent from one end of the first part FN1 to extend. The second branch part GEb2 may cross the first part FN1 while being overlapped with the first part FN1. The selection gate electrode SG may cross and be overlapped with the second part FN2 which is bent and from an opposite end portion of the first part FN1 of the fin-type active region FN to extend.

The fin-type active region FN includes the first branch part GEb1, the second branch part GEb2, and the first to third channel regions CH1, CH2, and CH3 respectively disposed under the selection gate electrode SG. The first to third channel regions CH1, CH2, and CH3 are sequentially arranged within the fin-type active region FN and are spaced apart from each other. In some example embodiments, the first channel region CH1 and the second channel region CH2 are channel regions of the first and second driving transistors DX1 and DX2, respectively, and the third channel region CH3 is a channel region of the selection transistor SX.

The source-drain regions SD are sequentially provided between opposite sides of each channel region and between two adjacent channel regions. According to some example embodiments, the source-drain regions SD includes the first source-drain region SD1 and the second source-drain region SD2 disposed at the opposite sides of the first channel region CH1, respectively, and the third source-drain region SD3 and the fourth source-drain region SD4 disposed at opposite sides of the third channel region CH3, when viewed in a plan view. The second source-drain region SD2 and the third source-drain region SD3 are disposed at opposite sides of the second channel region CH2.

In some example embodiments, the second source-drain region SD2 corresponds to the source region of the first driving transistor DX1 and the drain region of the second driving transistor DX2. The first source-drain region SD1 corresponds to the source region of the first driving transistor DX1, and the third source-drain region SD3 corresponds to the source region of the second driving transistor DX2. The first and third source-drain regions SD1 and SD3 may be connected to each other through separate wirings. In some example embodiments, the third source-drain region SD3, which is one of the source-drain regions SD, may be shared by the second driving transistor DX2 and the selection transistor SX. In some example embodiments, the third source-drain region SD3 also functions as the drain region of the selection transistor SX, and the fourth source-drain region SD4 functions as the source region of the selection transistor SX. The fourth source-drain region SD4 is connected to the separate wiring through the contact CT to output the electrical signal.

The driving gate electrode SF, the selection gate electrode SG, and the first to fourth source-drain regions SD1, SD2, SD3, and SD4 are connected to other components through the contact CT and separate wirings, as illustrated in FIG. 3. Specifically, the driving gate electrode SF is connected to the floating diffusion region FD, and the selection gate electrode SG is connected to the selection signal wiring. The first to third source-drain regions SD1, SD2, and SD3 are connected to each other through separate wirings to be connected to the drain region of the selection transistor SX. The fourth source-drain region SD4 output an electrical signal, which is received from the driving transistor DX to the source region of the selection transistor SX.

As described above, when one driving transistor DX and one selection transistor SX are formed using one fin-type active region FN, and when a portion of the source-drain region SD is shared by a portion of the driving transistor DX and the selection transistor SX, the driving transistor DX and the selection transistor SX need not to be connected to each other through a separate wiring while passing through the contact CT. Accordingly, the connection relationship of the wiring may be simplified and an issue such as parasitic capacitance resulting from the separate wiring may be prevented.

As described above, according to some example embodiments of the present inventive concepts, in the image sensor, noise-free pixel transistors may be implemented even in a narrow region. Accordingly, the image sensor according to some example embodiments of the present inventive concepts may be employed in a two-stack structure having a first structure and a second structure.

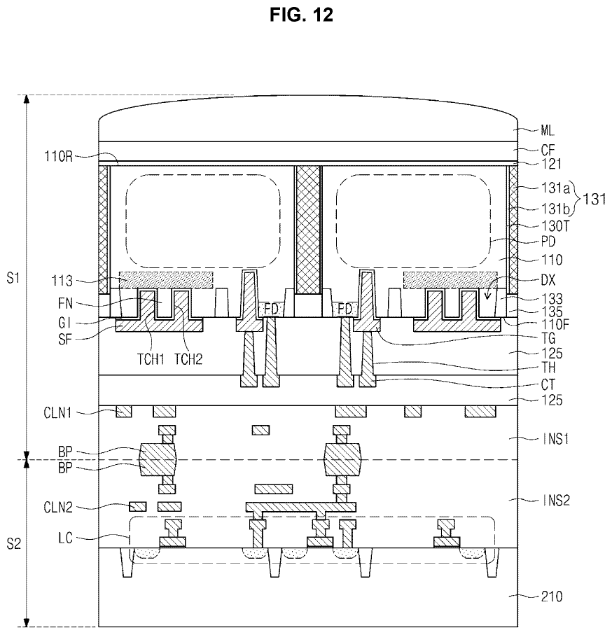

FIG. 12 is a cross-sectional view illustrating a two-stack structure in which the first structure S1 and the second structure S2 are stacked in an image sensor according to some example embodiments of the present inventive concepts.

Referring to FIG. 12, the image sensor may include the first structure S1 including the photodiode PD forming in the pixel array region, and the second structure S2 including a logic circuit.

A plurality of pixels correspond to the first structure S1 and the second structure S2. However, in drawings for the following description, only some of the plurality of pixels will be provided only for the convenience of explanation, and a drawing associated with the pad part will be omitted.

The first structure S1 includes, as described above, the semiconductor substrate 110 including the photodiode PD and the driving transistor DX, the first wiring part, the color filter CF, and the micro-lens ML, which are provided on the semiconductor substrate 110, and a first conductive lines CLN1. The first structure S1 may be disposed such that the first surface 110F to be inverted and provided according to some example embodiments described above, faces the second structure S2.

The second structure S2 may include a counter semiconductor substrate 210 including a logic circuit LC, and the second wiring part connected to the logic circuit LC.

The first wiring part of the first structure S1 may include the first conductive line CLN1 connected to the plurality of transistors described above, and a first insulating layer INS1 provided on the semiconductor substrate. The second wiring part of the second structure S2 may include the counter semiconductor substrate 210 including the logic circuit LC, second conductive lines CLN2 connected to the logic circuit LC, and a second insulating layer INS2 provided on the counter semiconductor substrate 210.

In some example embodiments, the first and second conductive lines CLN1 and CLN2 of the first structure S1 and the second structure S2 may include via patterns formed through at least portions of the first and second insulating layers INS1 and INS2, respectively, and may be provided in multiple layers. The bonding part may be provided at the uppermost portions inverted in the drawing of the first conductive lines CLN1 of the first structure S1 and the uppermost portions of the second conductive lines CLN2 of the second structure S2 and connecting the first structure S1 and the second structure S2. The bonding part may include a bonding pad BP disposed to face each other on the first structure S1 and the second structure S2. The bonding pad BP may be made of various conductive materials which may be bonded by heating or the like, and is integrated through bonding after manufacturing the first structure S1 and the second structure S2. The bonding pad BP may include, for example, a metal such as aluminum, copper, tungsten, titanium, tantalum, or an alloy thereof. According to some example embodiments of the present inventive concepts, the bonding pad BP may be made of copper, and thus the first and second structures S1 and S2 may be bonded by a copper-copper bonding. The first conductive line CLN1 of the first structure S1 and the second conductive line CLN2 of the second structure S2 may be connected to each other through the bonding pad BP, and the pixel may be driven through this connection.

According to some example embodiments of the present inventive concepts, the image sensor may reduce or minimize the noise resulting from the reduction in area of the channel of the transistor, and thus the functionality (e.g., image generating functionality, image generating performance, etc.) of the image sensor may be improved without compromising miniaturization of the image sensor. For example, the image sensor may be further miniaturized without compromising the functionality of the image sensor, based on the image sensor being configured to reduce or minimize the noise resulting from the reduction in area of the channel of the transistor.

Although some example embodiments of the present inventive concepts have been described for illustrative purposes, those skilled in the art will appreciate that various modifications, and substitutions are possible, without departing from the scope and spirit of the inventive concepts as disclosed in the accompanying claims. Accordingly, the technical scope of the inventive concepts is not limited to the detailed description of this specification, but should be defined by the claims.

While the present inventive concepts have been described with reference to some example embodiments thereof, it will be apparent to those of ordinary skill in the art that various changes and modifications may be made thereto without departing from the spirit and scope of the present inventive concepts as set forth in the following claims.

What is claimed is:

1. An image sensor, comprising:
a semiconductor substrate, the semiconductor substrate including a first surface and a second surface opposite to each other;
photodiodes within the semiconductor substrate; and
a plurality of driving transistors configured to generate electrical signals based on outputs from the photodiodes,
wherein the plurality of driving transistors include
a fin-type active region, the fin-type active region including
channel regions corresponding to separate, respective driving transistors of the plurality of driving transistors, and
source-drain regions, adjacent source-drain regions among the source-drain regions at opposite sides of each channel region among the channel regions, the source-drain regions protruding perpendicularly to the first surface, and
a driving gate electrode configured to cover a top surface and opposite sidewalls of the fin-type active region, and
wherein two adjacent driving transistors among the plurality of driving transistors physically share a particular source-drain region among the source-drain regions that is between the two adjacent driving transistors such that the particular source-drain region is a source region or a drain region of each of the two adjacent driving transistors.

2. The image sensor of claim 1, wherein the plurality of driving transistors are connected to each other in parallel.

3. The image sensor of claim 2, wherein the plurality of driving transistors share the driving gate electrode.

4. The image sensor of claim 2, wherein
the fin-type active region extends in at least one direction when viewed in a plan view, and
the driving gate electrode crosses an extension direction of the fin-type active region in each channel region of the channel regions while crossing the fin-type active region, such that separate, respective parts of the driving gate electrode overlap separate, respective parts of the fin-type active region in a vertical direction extending perpendicular to the first surface of the semiconductor substrate.

5. The image sensor of claim 4, wherein
the driving gate electrode includes a plurality of branch parts, and
a separate channel region of the channel regions corresponding to a separate branch part is under the separate branch part in the vertical direction.

6. The image sensor of claim 5, wherein the driving gate electrode further includes:
a main body part which is formed integrally with the branch parts without being separated from the branch parts to connect the plurality of branch parts to each other, such that the main body part and the plurality of branch parts are defined by separate, respective portions of a single, unitary piece of material.

7. The image sensor of claim 3, wherein the driving gate electrode includes doped polysilicon.

8. The image sensor of claim 1, wherein the fin-type active region is bent at least once when viewed in a plan view.

9. The image sensor of claim 8, wherein
the fin-type active region includes a first part extending in a first direction and a second part extending a second direction crossing the first direction, and
the driving gate electrode includes a first portion and a second portion, the first portion extending in the second direction to cross the first part of the fin-type active region, the second portion extending in the first direction to cross the second part of the fin-type active region.

10. The image sensor of claim 1, wherein
the fin-type active region is defined between a first trench and a second trench extending from the first surface of the semiconductor substrate to an inner part of the semiconductor substrate, and
the driving gate electrode includes a first part inside the first trench and a second part inside the second trench.

11. The image sensor of claim 1, wherein
the source-drain regions include at least three source-drain regions, the at least three source-drain regions are sequentially arranged from one side of the fin-type active region to an opposite side of the fin-type active region, and
odd-numbered source-drain regions of the at least three source-drain regions correspond to one of a source region or a drain region, and even-numbered source-drain regions of the at least three source-drain regions correspond to a remaining one of the source region or the drain region.

12. The image sensor of claim 1, further comprising:
a selection transistor connected to the plurality of driving transistors, the selection transistor configured to output a signal received from the plurality of driving transistors, in response to a selection signal,
wherein the selection transistor includes,
a particular channel region of the channel regions of the fin-type active region, and
particular source-drain regions of the source-drain regions of the fin-type active region at opposite sides of the particular channel region, and
wherein one of the particular source-drain regions of the selection transistor shares one of the source-drain regions of the plurality of driving transistors.

13. An image sensor, comprising:
a pixel array including a plurality of pixels including photodiodes and arranged in a matrix form in a first direction and a second direction crossing the first direction; and
a micro-lens on the pixel array, the micro-lens configured to condense light incident onto the plurality of pixels,
wherein the pixel array includes
a semiconductor substrate, the semiconductor substrate including a first surface and a second surface opposite to each other, wherein the photodiodes are within the semiconductor substrate, and
a plurality of driving transistors configured to generate electrical signals based on outputs of the photodiodes,
wherein the plurality of driving transistors include
a fin-type active region, the fin-type active region including
channel regions corresponding to separate, respective driving transistors of the plurality of driving transistors, and
source-drain regions, adjacent source-drain regions among the source-drain regions at opposite sides of each channel region among the channel regions, the source-drain regions protruding perpendicularly to the first surface, and
a driving gate electrode configured to cover a top surface and opposite sidewalls of the fin-type active region, and
wherein two adjacent driving transistors among the plurality of driving transistors physically share a particular source-drain region among the source-drain regions that is between the two adjacent driving transistors such that the particular source-drain region is a source region or a drain region of each of the two adjacent driving transistors.

14. The image sensor of claim 13, wherein the plurality of driving transistors are connected in parallel to each other and share the driving gate electrode.

15. The image sensor of claim 14, wherein at least a portion of the plurality of pixels includes:
a first pixel and a second pixel sequentially arranged in the first direction and/or the second direction, and
wherein the first pixel and the second pixel share one micro-lens.

16. The image sensor of claim 15, wherein the first pixel and the second pixel share the plurality of driving transistors.

17. The image sensor of claim 14, wherein at least a portion of the plurality of pixels includes:
a first pixel to a fourth pixel arranged in a form of a 2×2 matrix, and
wherein the first pixel to the fourth pixel share one micro-lens.

18. The image sensor of claim 15, further comprising:
a device isolation layer in a pixel trench provided in the semiconductor substrate, the device isolation layer defining the plurality of pixels.

19. The image sensor of claim 18, wherein
the device isolation layer at least partially defines a cutout part that omits the device isolation layer in a region between the first pixel and the second pixel, and
wherein the plurality of driving transistors are in the cutout part.

20. An image sensor, comprising:
a first structure including a plurality of pixels; and
a second structure stacked together with the first structure, the second structure including a logic circuit configured to control the plurality of pixels,
wherein each pixel of the plurality of pixels includes
a semiconductor substrate, the semiconductor substrate including
a first surface and a second surface opposite to each other,
photodiodes within the semiconductor substrate, and
a plurality of driving transistors configured to generate electrical signals based on outputs of the photodiodes,
wherein the plurality of driving transistors include
a fin-type active region, the fin-type active region including
channel regions corresponding to separate, respective driving transistors of the plurality of driving transistors, and
source-drain regions, adjacent source-drain regions among the source-drain regions at opposite sides of each channel region among the channel regions, the source-drain regions protruding perpendicularly to the first surface, and
a driving gate electrode configured to cover a top surface and opposite sidewalls of the fin-type active region, and
wherein two adjacent driving transistors among the plurality of driving transistors physically share a particular source-drain region among the source-drain regions that is between the two adjacent driving transistors such that the particular source-drain region is a source region or a drain region of each of the two adjacent driving transistors.
